(19) United States
(12) Patent Application Publication
(10) Pub. No.: US 2025/0318384 A1
(43) Pub. Date: Oct. 9, 2025

(54) DISPLAY DEVICE

(71) Applicant: SAMSUNG DISPLAY CO., LTD., YONGIN-SI (KR)

(72) Inventors: KIKYUNG YOUK, Yongin-si (KR); HONGAM KIM, Yongin-si (KR); SEUNGSUE RYU, Yongin-si (KR); DONG-HOON LEE, Yongin-si (KR)

(21) Appl. No.: 19/169,769

(22) Filed: Apr. 3, 2025

(30) Foreign Application Priority Data
Apr. 4, 2024 (KR) 10-2024-0046108

(51) Int. Cl. H10K 59/131; H10H 29/49; H10H 29/854; H10H 29/855; H10K 59/40; H10K 59/80; H10K 102/00

(52) U.S. Cl. CPC H10K 59/131; H10H 29/49; H10H 29/854; H10H 29/855; H10K 59/40; H10K 59/873; H10K 59/875; H10K 2102/311

(57) ABSTRACT

A display device includes a display area, a first signal pad, a second signal pad, an auxiliary circuit part, an organic protective layer, an insulating film, a first organic film, and a second organic film. The auxiliary circuit part disposed between the first signal pad and the second signal pad in a non-display area, and the organic protective layer overlaps the auxiliary circuit part. The insulating film includes a first insulating opening defined between the first signal pad and the auxiliary circuit part and a second insulating opening defined between the second signal pad and the auxiliary circuit part, and the insulating film may be disposed on the organic protective layer. The first and second organic film may be disposed respectively to fill at least a portion of the first and second insulating openings.

### CROSS-REFERENCE TO RELATED APPLICATIONS

This application claims priority under 35 U.S.C. § 119 to Korean Patent Application No. 10-20240046108, filed on Apr. 4, 2024, the entire contents of which are hereby incorporated by reference.

### BACKGROUND

### 1. Technical Field

The present disclosure relates to a display device, and more particularly to a display device including an insulating film defining an insulating opening.

### 2. Discussion of Related Art

Various display devices used in electronic devices such as televisions, mobile phones, table computers, navigation devices, and game consoles are being continually developed. The display device may include a display panel that detects an external input and displays an image.

The display panel may be electrically bonded to a driving chip. The driving chip may provide electrical signals for the display of the image. An area on which the driving chip is disposed may be a non-display area. The display panel may be bent to reduce the non-display area. Cracks may occur in the display panel due to bending stress input during the bending or a bonding pressure exerted during the bonding.

### SUMMARY

The present disclosure provides a display device having improved reliability.

An embodiment of the inventive concept provides a display device including: a display area; a bending area extending from the display area; a non-display area extending from the display area with the bending area disposed therebetween, the non-display area including; a first signal pad; a second signal pad spaced apart from the display area with the first signal pad disposed therebetween; an auxiliary circuit part disposed between the first signal pad and the second signal pad; an organic protective layer overlapping the auxiliary circuit part; an insulating film having a first insulating opening defined between the first signal pad and the auxiliary circuit part and a second insulating opening defined between the second signal pad and the auxiliary circuit part, the insulating film being disposed on the organic protective layer; a first organic film disposed to fill at least a portion of the first insulating opening; and a second organic film disposed to fill at least a portion of the second insulating opening.

In an embodiment, the first organic film and the second organic film may cover respective edge portions of the insulating film defining the first insulating opening and the second insulating opening, and the first organic film and the second organic film may be disposed apart from the first signal pad and the second signal pad.

An embodiment of the inventive concept provides an electronic device including: a light emitting element disposed in a first base area; a first signal pad electrically connected to the light emitting element and disposed in a second base area adjacent to the first base area; a second signal pad spaced apart from the first base area with the first signal pad disposed therebetween and disposed in the second base area; an auxiliary circuit part disposed between the first signal pad and the second signal pad in the second base area; an organic protective layer overlapping the auxiliary circuit part and disposed in the second base area; an insulating film having a first insulating opening defined between the first signal pad and the auxiliary circuit part and a second insulating opening defined between the second signal pad and the auxiliary circuit part, the insulating film being disposed on the organic protective layer in the second base area; a first organic film disposed to fill at least a portion of the first insulating opening in the second base area; and a second organic film disposed to fill at least a portion of the second insulating opening in the second base area.

In an embodiment, the first base area may include a display area and the second base area may include a non-display area, and the first organic film and the second organic film may be spaced apart from each other with the organic protective layer therebetween in a direction perpendicular to a thickness direction.

In an embodiment, each of the first organic film and the second organic film may not overlap the first signal pad and the second signal pad.

In an embodiment, the electronic device may further include an input sensing layer including a sensing conductive layer and a sub-insulating layer disposed on the sensing conductive layer, the input sensing layer being disposed on the light emitting element, wherein each of the first organic film and the second organic film may include the same organic material as the sub-insulating layer.

In an embodiment, the electronic device may further include an organic encapsulation layer disposed on the light emitting element, wherein each of the first organic film and the second organic film may include the same organic material as the organic encapsulation layer.

In an embodiment, the electronic device may further include an optical layer comprising at least one of a pigment or a dye and disposed on the light emitting element, wherein each of the first organic film and the second organic film may include the same organic material as the optical layer.

In an embodiment, the optical layer may include: an optical pattern part in which a pattern opening is defined; and a sub-optical layer comprising at least one of the pigment or the dye and configured to serve as a planarization layer disposed to fill the pattern opening, wherein each of the first organic film and the second organic film may include the same organic material as the sub-optical layer.

In an embodiment, the optical layer may include: an optical pattern part in which a pattern opening is defined; a filter part including at least one of the pigment or the dye and disposed to fill the pattern opening; and an over-layer disposed on the optical pattern part and the filter part, wherein each of the first organic film and the second organic film may include the same organic material as the over-layer.

In an embodiment, the light emitting element may include a first electrode, a second electrode disposed on the first electrode, and an emission layer disposed between the first electrode and the second electrode, and the filter part may overlap the emission layer.

In an embodiment, on a plane, the first organic film comprises a first portion extending in a first direction perpendicular to a thickness direction, and the second organic film comprises a second portion extending in the first direction, wherein the first organic film may further include a third portion extending from the first portion in a second direction different from the first direction, and wherein the second direction may be a direction away from the second signal pad.

In an embodiment, on a plane, the first organic film comprises a first portion extending in a first direction perpendicular to a thickness direction, and the second organic film comprises a second portion extending in the first direction, wherein on the plane, the second organic film may further include a fourth portion extending from the second portion in a third direction different from the first direction, and wherein the third direction may be a direction away from the first signal pad.

In an embodiment, each of the first organic film and the second organic film may include a plurality of sub-organic films spaced apart from each other in a direction perpendicular to a thickness direction.

In an embodiment, the insulating film may overlap an edge portion of the first signal pad and an edge portion of the second signal pad, and the insulating film may have a first pad opening exposing the first signal pad and a second pad opening exposing the second signal pad.

In an embodiment, the auxiliary circuit part may include an auxiliary line disposed on the same layer as at least one of the first signal pad or the second signal pad.

An embodiment of the inventive concept provides a display device including: a light emitting element disposed in a first base area; a first signal pad electrically connected to the light emitting element and disposed in a second base area adjacent to the first base area; a second signal pad spaced apart from the first base area with the first signal pad disposed therebetween and disposed in the second base area; an insulating film having a first insulating opening defined between the first signal pad and the second signal pad, and a second insulating opening spaced apart from the first insulating opening with the first signal pad therebetween, the insulating film being disposed in the second base area; a first organic film disposed to fill at least a portion of the first insulating opening in the second base area; and a second organic film disposed to fill at least a portion of the second insulating opening in the second base area.

In an embodiment, the display device may further include an auxiliary circuit part disposed between the first signal pad and the second signal pad in the second base area; an organic protective layer overlapping the auxiliary circuit part and disposed in the second base area, wherein the insulating film is disposed on the organic protective layer in the second base area, wherein the first insulating opening is defined between the first signal pad and the auxiliary circuit part, and wherein the insulating film further comprises a third insulating opening defined between the second signal pad and the auxiliary circuit part; and a third organic film disposed to fill at least a portion of the third insulating opening in the second base area.

In an embodiment, on a plane, the third organic film comprises a fifth portion extending in a first direction perpendicular to a thickness direction.

In an embodiment, on the plane, the third organic film may further comprise a sixth portion extending from the fifth portion in a fourth direction different from the first direction, wherein the fourth direction is a direction approaching the second signal pad.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a perspective view of a display device according to an embodiment of the inventive concept;

FIG. 2 is an exploded perspective view of the display device according to an embodiment of the inventive concept;

FIG. 3 is a cross-sectional view illustrating a portion of the display device according to an embodiment of the inventive concept;

FIG. 4 is a plan view illustrating a portion of the display device according to an embodiment of the inventive concept;

FIG. 5 is a plan view illustrating a portion of the display device according to an embodiment of the inventive concept;

FIG. 6 is an exploded perspective view illustrating a portion of the display device according to an embodiment of the inventive concept;

FIG. 7A is a cross-sectional view illustrating a portion of the display device according to an embodiment of the inventive concept;

FIG. 7B is a cross-sectional view illustrating a portion of the display device according to an embodiment of the inventive concept;

FIG. 8 is a plan view illustrating a portion of the display device according to an embodiment of the inventive concept;

FIG. 9A is an enlarged plan view of an area AA′ of FIG. 8;

FIG. 9B is a plan view illustrating a portion of the display device according to an embodiment of the inventive concept;

FIG. 10A is an enlarged plan view of an area BB′ of FIG. 8;

FIG. 10B is a plan view illustrating a portion of the display device according to an embodiment of the inventive concept;

FIG. 10C is a plan view illustrating a portion of the display device according to an embodiment of the inventive concept;

FIG. 11A is a plan view illustrating a portion of the display device according to an embodiment of the inventive concept;

FIG. 11B is a plan view illustrating a portion of the display device according to an embodiment of the inventive concept;

FIG. 11C is a plan view illustrating a portion of the display device according to an embodiment of the inventive concept;

FIG. 11D is a plan view illustrating a portion of the display device according to an embodiment of the inventive concept;

FIG. 11E is a plan view illustrating a portion of the display device according to an embodiment of the inventive concept; and

FIG. 11F is a plan view illustrating a portion of the display device according to an embodiment of the inventive concept.

### DETAILED DESCRIPTION

Since the present disclosure may have diverse modified embodiments, specific embodiments are illustrated in the drawings and are described in the detailed description of the inventive concept. However, this does not limit the present disclosure within specific embodiments and it should be understood that the present disclosure covers all the modifications, equivalents, and replacements within the idea and technical scope of the present disclosure.

In this specification, it will also be understood that when a first component (or region, layer, portion) is referred to as being ‘on’, ‘connected to’, or ‘coupled to’ a second component, the first component can be directly disposed/connected/coupled on/to the second component, or an intervening third component may also be present.

Like reference numerals refer to like elements throughout. Also, in the figures, the thickness, ratio, and dimensions of components may be exaggerated for clarity of illustration. The term “and/or” includes any and all combinations of one or more of the associated components.

It will be understood that although the terms such as ‘first’ and ‘second’ are used herein to describe various elements, these elements should not be limited by these terms. The terms are only used to distinguish components from each other. For example, a first element referred to as a first element can be referred to as a second element elsewhere without departing from the scope of the appended claims. The terms of a singular form may include plural forms unless referred to the contrary.

Also, “under”, “below”, “above’, “upper”, and the like are used for explaining relation association of components illustrated in the drawings. The terms may be a relative concept and described based on directions expressed in the drawings.

The meaning of ‘include’ or ‘comprise’ specifies a property, a fixed number, a step, an operation, an element, a component or a combination thereof, but does not exclude other properties, fixed numbers, steps, operations, elements, components or combinations thereof.

Unless otherwise defined, all terms (including technical and scientific terms) used herein have the same meaning as commonly understood by a person of ordinary skill in the art to which this invention belongs. In addition, terms such as those defined in commonly used dictionaries should be interpreted as having meanings consistent with their meanings in the context of the relevant technology, and unless explicitly defined, it should not be interpreted in an overly idealistic or overly formal sense.

Hereinafter, a display device according to an embodiment of the inventive concept will be described with reference to the accompanying drawings.

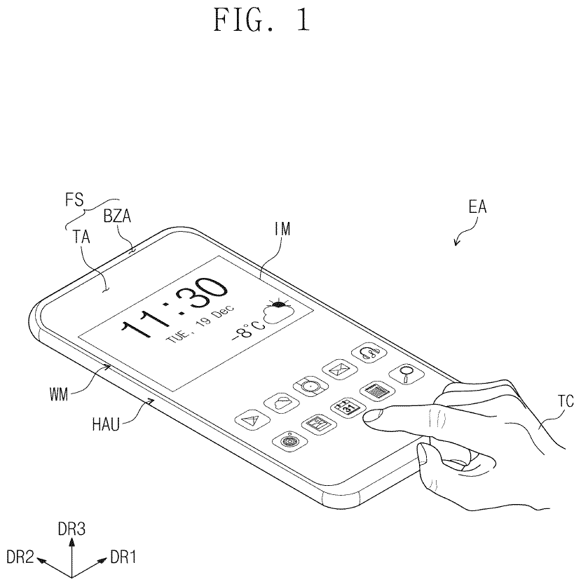

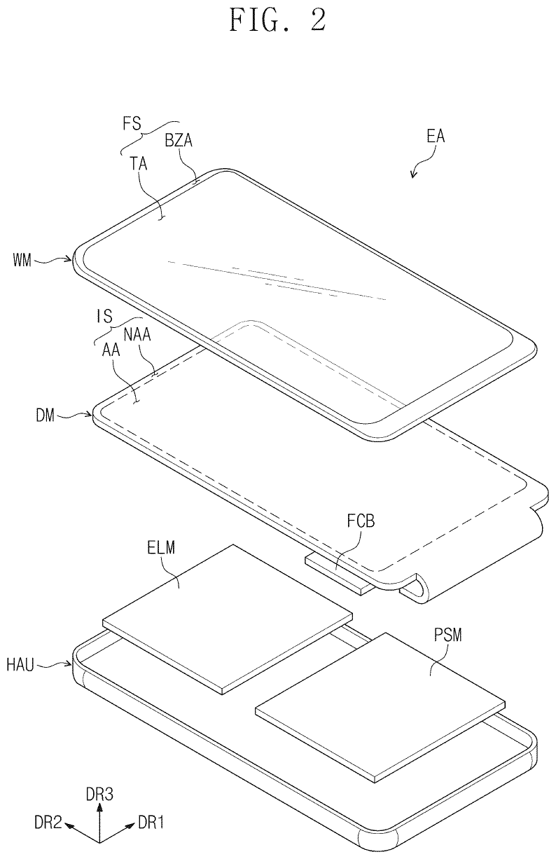

FIG. 1 is a perspective view of a display device EA according to an embodiment of the inventive concept. FIG. 2 is an exploded perspective view of the display device EA according to an embodiment of the inventive concept. Referring to FIG. 1 and FIG. 2, the display device EA may display an image IM and detect an external input TC. The display device EA may display the image IM according to an electrical signal. The display device EA may generate an electrical signal according to the external input. For example, the display device EA may be a monitor, a mobile phone, a tablet, a navigation device, a game console, or a wearable device, but embodiments are not limited thereto. FIG. 1 illustrates an example in which the display device EA is the mobile phone. In this specification, an electronic device may be the display device EA or may include the display device EA.

The display device EA may be rigid or flexible. The term “flexible” may mean having a bendable property. For example, a flexible display device may include anything from a completely foldable structure to a structure that is capable of bent at a level of a few nanometers. For example, the flexible display device EA may include a curved display device, a rollable display device, or a foldable display device.

The display device EA may display the image IM through a display surface FS disposed parallel to a plane defined by a first direction DR1 and a second direction DR2. The image IM may include a still image, a dynamic image, or a moving image. In FIG. 1, a clock and icons are illustrated as an example of the image IM.

The display surface FS of the display device EA may be implemented as a plane or a curved surface bent from one or more sides of the plane. The display surface FS may correspond to a front surface of the display device EA and also may correspond to a front surface of a window WM. Hereinafter, the display surface FS of the display device EA and the front surface FS of the window WM may be used interchangeably.

In this specification, the first direction DR1 and the second direction DR2 may be perpendicular to each other. A third direction DR3 (hereinafter also referred as a thickness direction DR3) may be a normal direction with respect to a plane defined by the first direction DR1 and the second direction DR2. A thickness direction of the display device EA may be parallel to the third direction DR3. Top (or front) and bottom (or rear) surfaces may be disposed opposite to each other in the third direction DR3, and a normal direction of each of the top (or front) and bottom (or rear) surfaces may be extend parallel to the third direction DR3. The top surface (or upper side and upper portion) may refer to a surface close to (or direction approaching) the display surface FS, and the bottom surface (or lower side and lower portion) may refer a surface spaced apart from (or direction away from) the display surface FS. A cross-section may refer to a surface parallel to the thickness direction DR3, and the plane may refer to a surface perpendicular to the thickness direction DR3. The plane may refer to a plane defined by the first direction DR1 and the second direction DR2.

The directions indicated as the first to third directions DR1, DR2, and DR3, may be a relative concept and thus changed into different directions. In addition, the directions indicated by the first to third directions DR1, DR2, and DR3 may be described as first to third directions, and also, the same reference numerals may be used.

The display device EA according to an embodiment may detect the external input TC applied from the outside. The external input TC may include various types of inputs such as touch, force, pressure, temperature, or light. In FIG. 1, the external input TC is illustrated as a user's hand applied to the front surface of the display device EA. However, this is illustrated as an example, and the external input TC may include an input applied close to the display device EA, such as pen contact or hovering above the front surface.

The display device EA may detect the user's input through the display surface FS defined on the front surface. The display device EA may react to the detected input signal. However, an area of the display device EA that detects the external input TC is not limited to the front surface of the display device EA and may be changed depending on a design of the display device EA. For example, the display device EA may detect a user's input applied to the side or rear surface of the display device EA.

Referring to FIG. 2, the display device EA may include a window WM, a display module DM, an electronic module ELM, a power module PSM, and a housing HAU. The window WM and the housing HAU may be coupled to each other to define an outer portion of the display device EA.

The window WM may be disposed on the display module DM. The window WM may cover a front surface IS of the display module DM. The window WM may protect the display module DM from external impacts and scratches. The window WM may be coupled to the display module DM through an adhesive layer.

The window WM may include an optically transparent material. The window WM may include an insulating material. For example, the window WM may include glass or a synthetic resin as a base film. The window WM may have a single-layered or multi-layered structure. For example, the multi-layered window WM may include synthetic resin films bonded through an adhesive or may include a glass film and a synthetic resin film bonded through an adhesive. The window WM may further include a functional layer such as an anti-fingerprint layer, a phase control layer, or a hard coating layer disposed on an optically transparent base film.

The front surface FS of the window WM may correspond to the front surface of the display device EA. The front surface FS of the window WM may include a transmission area TA and a bezel area BZA.

The transmission area TA may be an optically transparent area. The transmission area TA may transmit the image IM (FIG. 1) provided by the display module DM. In FIG. 1 and FIG. 2, the transmission area TA is illustrated as a rectangular shape, but the transmission area TA is not limited thereto and may have various shapes such as a circular shape or a polygonal shape.

The bezel area BZA may be an area having light transmittance less than that of the transmission area TA. The bezel area BZA may be an area on which a material having a predetermined color is printed. The bezel area BZA may inhibit or prevent light from being transmitted therethrough, and may inhibit or prevent a component of the display module DM, which is disposed overlapping the bezel area BZA, from being viewed from the outside. In this specification, the overlapping of a first component and a second component is not limited to the case in which the first component and the second component may have the same area and the same shape, but may include a case in which the first and second components may have different areas and/or different shapes.

The bezel area BZA may be disposed adjacent to the transmission area TA. The shape of the transmission area TA may be substantially defined by the bezel area BZA. For example, the bezel area BZA may be disposed outside the transmission area TA and may surround the transmission area TA. However, this is merely an example, and the bezel area BZA may be adjacent to only one or more sides of the transmission area TA or may be disposed on a side rather than the front surface of the display device EA. In addition, the bezel area BZA may be omitted.

The display module DM may be disposed between the window WM and the housing HAU. The display module DM may display the image IM and may detect the external input TC. The image IM may be displayed on the front surface IS of the display module DM. The front surface IS of the display module DM may include an active area AA and a peripheral area NAA.

The active area AA may be an area that is activated according to an electrical signal. For example, the active area AA may be an area on which the image IM may be displayed, and in which the external input TC may be detected. The active area AA may overlap at least a portion of the transmission area TA. Thus, the user may see the image IM through the transmission area TA and/or provide the external input TC. However, this is merely an example, and the area on which the image IM may be displayed and the area on which the external input TC may detected within the active area AA may be separated from each other and are not limited to any embodiment.

The peripheral area NAA may be disposed adjacent to the active area AA. For example, the peripheral area NAA may surround the active area AA. A driving circuit or a driving line for driving the active area AA may be disposed on the peripheral area NAA. The peripheral area NAA may overlap at least a portion of the bezel area BZA. Components disposed on the peripheral area NAA may be obscured from being viewed from the outside by the bezel area BZA. For example, components disposed on the peripheral area NAA may not be viewed from the outside by the bezel area BZA.

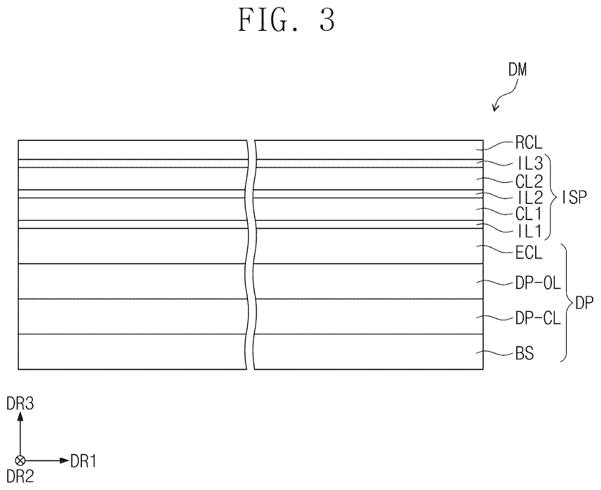

Referring to FIG. 3, the display module DM may include a display panel DP and an input sensing layer ISP. The display panel DP may display the image IM. The input sensing layer ISP may detect the external input TC.

A portion of the display module DM may be bent with respect to a bending axis extending in the first direction DR1. That is, the portion of the display module DM may be bent toward the rear surface of the display module DM to overlap the active area AA. A flexible circuit board FCB may be connected to a portion of the bent display module DM. When the display module DM is bent, the flexible circuit board FCB may overlap the display module DM in the thickness direction DR3.

The flexible circuit board FCB may be disposed on a side of the display module DM. The flexible circuit board FCB may be electrically connected to the display module DM. The flexible circuit board FCB may generate an electrical signal provided to the display module DM or receive a signal generated by the display module DM to determine resultant values including a position, at which the external input TC is detected, or intensity information.

The display device EA may further include an electronic module ELM and a power module PSM. The electronic module ELM and the power module PSM may be disposed below the display module DM. The electronic module ELM and the power module PSM may be electrically connected to each other. The electronic module ELM and the power module PSM may be electrically connected through a separate circuit board.

The power module PSM may supply power for an operation of the display device EA. For example, the power module PSM may include a typical battery module.

The electronic module ELM may include various functional modules that may operate the display device EA. For example, the electronic module ELM may include at least one of a control module, a wireless communication module, an image input module, an audio input module, an audio output module, a memory, an optical module, or an external interface module. The electronic module ELM may include a main circuit board. The modules of the electronic module ELM may be mounted on the main circuit board or may be electrically connected to the main circuit board through a separate circuit board.

In the electronic modules ELM, the control module may control an overall operation of the display device EA. For example, the control module may activate or deactivate the display module DM according to a user input. The control module may include at least one microprocessor. In the electronic modules ELM, the optical module may include a camera module, a proximity sensor, a biometric sensor that recognizes a portion of the user's body (e.g., fingerprint, iris, or face), or a lamp that outputs light.

The housing HAU may be coupled to the window WM to provide an internal space that may accommodate at least one of the display module DM, the electronic module ELM, the power module PSM, or the flexible circuit board FCB. The housing HAU may include a material having relatively high rigidity. For example, the housing HAU may include glass, plastic, or a metal, or may include a plurality of frames and/or plates made of a combination of at least two of glass, plastic, or a metal. The housing HAU may protect the components of the display device EA by absorbing an impact applied from the outside or inhibiting foreign substances/moisture from be penetrated from the outside.

FIG. 3 is a cross-sectional view of the display module DM according to an embodiment of the inventive concept. Referring to FIG. 3, the display module DM may include a display panel DP, an input sensing layer ISP, and an optical layer RCL. The display panel DP, the input sensing layer ISP, and the optical layer RCL may be sequentially laminated.

The display panel DP may display an image according to an electrical signal. The display panel DP according to an embodiment may be an emissive display panel, but is not particularly limited thereto. For example, the display panel DP may be an organic light emitting display panel, an inorganic light emitting display panel, a quantum dot light emitting display panel, a micro LED display panel, or a nano LED display panel. The display panel DP may include a base layer BS, a circuit layer DP-CL, a display element layer DP-OL, and an encapsulation layer ECL, which may be sequentially laminated in the third direction DR3.

The base layer BS may be a rigid substrate or a flexible substrate capable of being bent, folded, or rolled. For example, the base layer BS may be a glass substrate, a metal substrate, or a polymer substrate. However, embodiments are not limited thereto, and the base layer BS may include an inorganic layer, an organic layer, or a composite material layer. The base layer BS may provide a base surface on which the circuit layer DP-CL may be disposed.

The base layer BS may include a single layer or multiple layers. For example, the base layer BS may include a first synthetic resin layer, a multi-layered or single-layered inorganic layer, and a second synthetic resin layer disposed above the multi-layered or single-layered inorganic layer. Each of the first synthetic resin layer and the second synthetic resin layer may include a polyimide-based resin. In addition, each of the first synthetic resin layer and the second synthetic resin layer may include at least one of an acrylate-based resin, a methacrylic-based resin, a polyisoprene-based resin, a vinyl-based resin, an epoxy-based resin, a urethane-based resin, a cellulose-based resin, a siloxane-based resin, a polyamide-based resin, or a perylene-based resin. In this specification, the “˜˜-based” resin means containing a “˜˜” functional group.

The circuit layer DP-CL may be disposed on the base layer BS. The circuit layer DP-CL may include at least one insulating layer, a semiconductor pattern, and a conductive pattern. The insulating layer, the semiconductor pattern, and the conductive pattern, which may be included in the circuit layer DP-CL, may be provided with one or more driving elements such as transistors, signal lines, or pads.

The display element layer DP-OL may be disposed on the circuit layer DP-CL. The display element layer DP-OL may include light emitting elements configured to emit light. For example, the light emitting elements may include an organic light emitting element, an inorganic light emitting element, a quantum dot light emitting element, a micro LED, or a nano LED. The light emitting elements of the display element layer DP-OL may be electrically connected to the driving elements of the circuit layer DP-CL and may emit light according to electrical signals provided by the driving elements.

The encapsulation layer ECL may be disposed on the display element layer DP-OL. The encapsulation layer ECL may seal the light emitting elements. The encapsulation layer ECL may include at least one thin film. The thin film may improve optical efficiency of the display element layer DP-OL. The thin film may protect the display element layer DP-OL. For example, the encapsulation layer ECL may include at least one of an inorganic encapsulation layer or an organic encapsulation layer. The inorganic encapsulation layer of the encapsulation layer ECL may protect the light emitting elements from moisture/oxygen. The organic encapsulation layer of the encapsulation layer ECL may protect the light emitting elements from foreign substances such as dust particles.

The input sensing layer ISP may be disposed directly on the display panel DP. For example, the input sensing layer ISP may be disposed on the encapsulation layer ECL of the display panel DP. The input sensing layer ISP may be formed on the display panel DP through a continuous process, and the input sensing layer ISP and the display panel DP may be coupled to each other without a separate adhesive layer. That is, components of the input sensing layer ISP may be disposed on the base surface provided by the display panel DP.

In this specification, a first component may be disposed/formed directly on a second component, such that a third component may not disposed/formed between the first and second components. That is, the first component may be disposed/formed directly on the second component, such that the first component is in contact with the second component.

The input sensing layer ISP may detect an external input. The input sensing layer ISP may provide an input signal including information about the external input and the display panel DP may display an image corresponding to the external input. The input sensing layer ISP may be driven in various manners such as a capacitive, resistive, infrared, acoustic, or pressure manner, and the driving method of the input sensing layer ISP may not be limited to any one method as long as the input sensing layer ISP detects the external input. Hereinafter, the input sensing layer ISP will be described as being driven in the capacitive manner. However, embodiments are not limited thereto.

The input sensing layer ISP may include a base insulating layer IL1, a first sensing conductive layer CL1, a first sub-insulating layer IL2, a second sensing conductive layer CL2, and a second sub-insulating layer IL3, which may be sequentially laminated in the third direction DR3. The base insulating layer IL1 of the input sensing layer ISP may be in contact with the encapsulation layer ECL. However, embodiments are not limited thereto, and at least one of the base insulating layer IL1 or the second sub-insulating layer IL3 may be omitted.

Each of the first sensing conductive layer CL1 and the second sensing conductive layer CL2 may include a conductive pattern layer having a single-layered or multi-layered structure. The multi-layered conductive pattern layer may include at least two of transparent conductive layers and metal layers. The multi-layered conductive pattern layer may include metal layers containing different metals. The transparent conductive layer may include at least one of indium tin oxide (ITO), indium zinc oxide (IZO), zinc oxide (ZnO), indium tin zinc oxide (ITZO), PEDOT, a metal nanowire, or graphene. The metal layer may include at least one of molybdenum (Mo), silver (Ag), titanium (Ti), copper (Cu), or aluminum (Al), or alloys thereof. For example, each of the first sensing conductive layer CL1 and the second sensing conductive layer CL2 may have a two-layered structure of ITO/Cu or a three-layered structure of titanium/aluminum/titanium. However, this is merely an example, and embodiments are not limited thereto.

Each of the base insulating layer IL1, the first sub-insulating layer IL2, and the second sub-insulating layer IL3 may include at least one of an inorganic layer or an organic layer. For example, the inorganic layer may include at least one of aluminum oxide, titanium oxide, silicon oxide, silicon oxynitride, zirconium oxide, or hafnium oxide, and the organic layer may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyimide-based resin, a polyamide-based resin, or a perylene-based resin. However, this is merely an example, and the materials of the inorganic layer and the organic layer are not limited thereto. The base insulating layer IL1 may include an inorganic layer, and each of the first sub-insulating layer IL2 and the second sub-insulating layer IL3 may include an organic layer, but embodiments are not limited thereto.

The optical layer RCL may be disposed on the input sensing layer ISP. The optical layer RCL may include at least one of a pigment or a dye. The optical layer RCL may be a layer that selectively transmits light emitted from the display panel DP. The optical layer RCL may be a layer that reduces reflectance of external light incident from the outside.

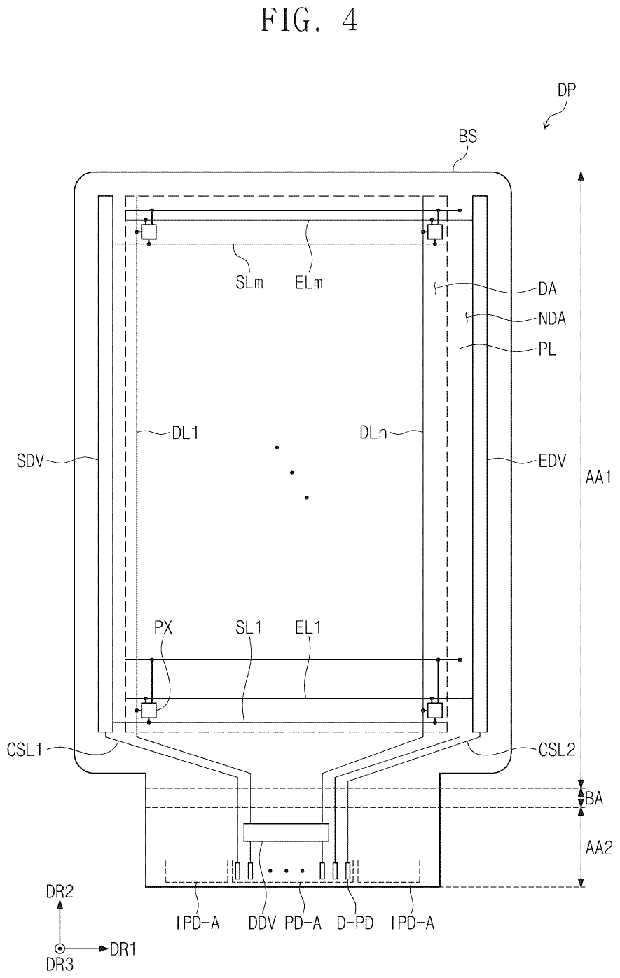

FIG. 4 is a plan view illustrating a portion of the display panel DP according to an embodiment of the inventive concept. Referring to FIG. 4, the display panel DP may include a base layer BS, a plurality of pixels PX, and signal lines SL1 to SLm, DL1 to DLn, EL1 to ELm, CSL1, CSL2, and PL electrically connected to the pixels PX, a scan driver SDV, an emission driver EDV, a driving chip DDV, and display pads D-PD.

The base layer BS may include a base surface on which components of the display panel DP may be disposed. The components may include electrical elements and lines. The base layer BS may include a first base area AA1, a bending area BA, and a second base area AA2. The first base area AA1, the bending area BA, and the second base area AA2 may be separated from each other in the second direction DR2. The bending area BA may extend from the second base area AA2 in the second direction DR2. The first base area AA1 may extend from the bending area BA in the second direction DR2. In the second direction DR2, the first base area AAl and the second base area AA2 may be spaced apart from each other with the bending area BA disposed therebetween.

The first base area AA1 may include a display area DA. The display area DA may be an area in which the light emitting elements of the pixels PX may be disposed. The pixels PX may display an image through the display area DA. The display area DA may correspond to the active area AA (see FIG. 2) of the display module DM (see FIG. 2) and may overlap the transmission area TA (see FIG. 2).

At least a portion of the first base area AAl may be defined as a non-display area NDA. The non-display area NDA may be an area which is adjacent to the display area DA and on which an image is not displayed. The non-display area NDA may surround the display area DA. The scan driver SDV, the emission driver EDV, the driving chip DDV, which drives the pixels PX, and the display pads D-PD, which may be electrically connected to the signal lines SL1 to SLm, DL1 to DLn, EL1 to ELm, CSL1, CSL2, and PL, may be disposed in the non-display area NDA of the first base area AA1. The signal lines SL1 to SLm, DL1 to DLn, EL1 to ELm, CSL1, CSL2, and PL electrically connected to the pixels PX may be disposed to extend in the non-display area NDA. The non-display area NDA may further include the bending area BA and the second base area AA2. The signal lines DL1 to DLn, CSL1, CSL2, and PL electrically connected to the pixels PX may be disposed to extend in the bending area BA and the second base area AA2.

The bending area BA may be an area that is bent with respect to the bending axis extending in the first direction DR1. That is, the bending area BA may be bent toward the rear surface of the display panel DP corresponding to the first base area AA1. The second base area AA2 extending from a side of the bending area BA may overlap the first base area AA1 in the thickness direction DR3 by bending the bending area BA. That is, when the display panel DP is bent, the second base area AA2 may be disposed on the rear surface of the display panel DP corresponding to the first base area AA1.

In the first direction DR1, a width of each of the bending area BA and the second base area AA2 may be less than a width of the first base area AA1. However, this is merely an example, and at least one of the widths of the bending area BA and the second base area AA2 in the first direction DR1 may be the same as the width of the first base area AA1, but is not limited thereto. In a case that the bending area BA has a width less than that of the first base area AA1 in a direction parallel to the direction in which the bending axis extends, the bending area BA may be more easily bent.

The second base area AA2 may be an area that may be disposed below the first base area AA1. For example, the second base area AA2 may be disposed flat to the first base area AAl by bending the bending area BA. The second base area AA2 may be an area on which the signal lines extending toward the display pads D-PD via the bending area BA from the first base area AA1 in the signal lines SL1 to SLm, DL1 to DLn, EL1 to ELm, CSL1, CSL2, and PL and the driving chip DDV are disposed.

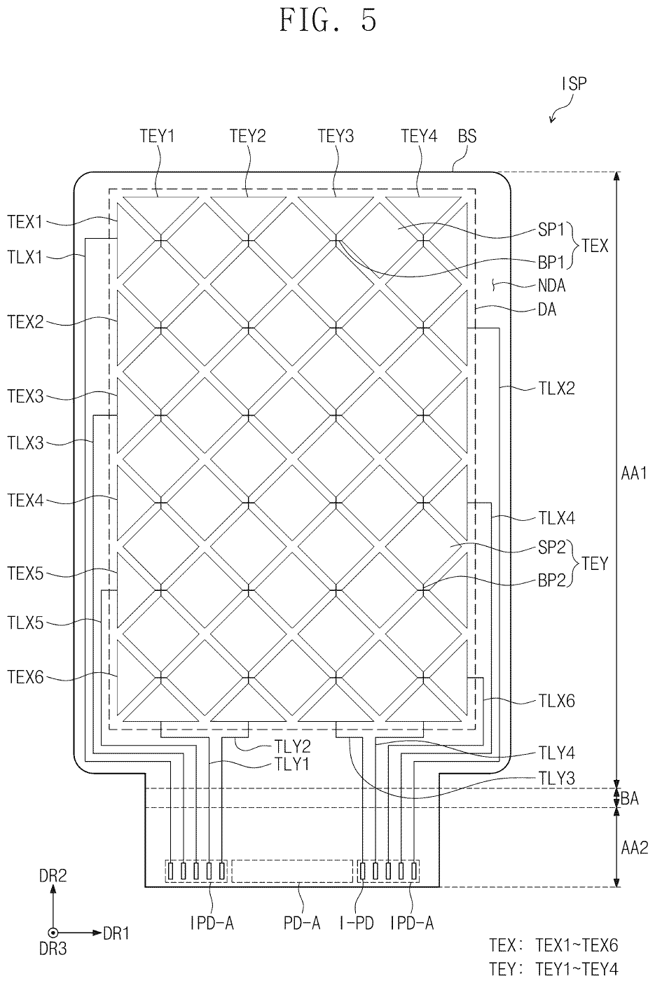

The area on which the display pads D-PD are disposed and the area on which the sensing pads I-PD (see FIG. 5) are disposed may be divided into a display pad area PD-A and the sensing pad area IPD-A, respectively. In FIG. 4, the display pad area PD-A and the sensing pad area IPD-A may be separated from each other in the first direction DR1. For example, the sensing pad area IPD-A may be disposed adjacent to sides of the second base area AA2 in the first direction DR1, and the display pad area PD-A may be provided at a central portion adjacent to a lower end portion of the second base area AA2. However, embodiments are not limited thereto, and the arrangement positions of the display pads D-PD and the sensing pads I-PD (see FIG. 5) may be changed in various manners.

The flexible circuit board FCB (see FIG. 2) may be disposed in the second base area AA2 in which the display pads D-PD and the sensing pads I-PD (see FIG. 5) may be disposed to be electrically connected to the display pads D-PD and the sensing pads I-PD (see FIG. 5). The flexible circuit board FCB (see FIG. 2) disposed adjacent to the lower end portion of the second base area AA2 may be disposed on the rear surface of the display panel DP by bending the bending area BA. As the second base area AA2 and the flexible circuit board FCB (see FIG. 2) are disposed below the first base area AA1 of the display device EA (see FIG. 2), the bezel area of the display device EA (see FIG. 2) may be reduced.

Each of the pixels PX may include a pixel driving circuit including transistors (e.g., a switching transistor and a driving transistor) and at least one capacitor, and a light emitting element electrically connected to the pixel driving circuit. The pixels PX may generate light in response to an electrical signal applied to each of the pixels PX and may display an image through the display area DA. A portion of the pixels PX may include a transistor disposed in the non-display area NDA, but is not limited to any embodiment.

The scan driver SDV and the emission driver EDV may be disposed in the non-display area NDA corresponding to the first base area AA1. The driving chip DDV may be disposed in the non-display area NDA corresponding to the second base area AA2. The driving chip DDV may be provided in the form of an integrated circuit chip mounted in the non-display area NDA of the display panel DP. However, embodiments are not limited thereto, and the driving chip DDV may be mounted on the flexible circuit board FCB (see FIG. 2).

The signal lines SL1 to SLm, DL1 to DLn, EL1 to ELm, CSL1, CSL2, and PL may include scan lines SL1 to SLm, data lines DL1 to DLn, and emission lines EL1 to Elm, first and second control lines CSL1 and CSL2, and a power line PL. Here, m and n may be natural numbers larger than 1.

The data lines DL1 to DLn may be insulated from and intersect the scan lines SL1 to SLm and the emission lines EL1 to ELm. For example, the scan lines SL1 to SLm may extend in the first direction DR1 and be electrically connected to the scan driver SDV. The data lines DL1 to DLn may extend in the second direction DR2 and be electrically connected to the driving chip DDV. The emission lines EL1 to ELm may extend in the first direction DR1 and be electrically connected to the emission driver EDV.

The power line PL may include a portion extending in the first direction DR1 and a portion extending in the second direction DR2. The portion extending in the first direction DR1 and the portion extending in the second direction DR2 of the power line PL may be disposed on different layers or may be disposed on the same layer and have an integrated shape. The portion of the power line PL extending in the first direction DR1 may be electrically connected to the pixels PX and the portion extending in the second direction DR2. The portion of the power line PL extending in the second direction DR2 may be disposed in the non-display area NDA and may be electrically connected to the display pads D-PD via the bending area BA and the second base area AA2 from the first base area AA1. The power line PL may provide a first voltage to the pixels PX.

The first control line CSL1 may be electrically connected to the scan driver SDV and may extend toward a lower end portion of the second base area AA2 via the bending area BA. The second control line CSL2 may be electrically connected to the emission driver EDV and may extend toward the lower end portion of the second base area AA2 via the bending area BA.

The display pads D-PD may be disposed adjacent to the lower end portion of the second base area AA2. The display pads D-PD may be disposed closer to the lower end portion of the base layer BS than the driving chip DDV in the second base area AA2. The display pads D-PD may be disposed to be spaced apart from each other in the first direction DR1. Each of the power line PL, the first control line CSL1, and the second control line CSL2 may be electrically connected to the corresponding display pad D-PD of the display pads D-PD. Each of the data lines DL1 to DLn may be electrically connected to the corresponding one of the display pads D-PD through the driving chip DDV.

The display pads D-PD may be electrically connected to the flexible circuit board FCB (see FIG. 2) through an anisotropic conductive adhesive layer, and the electrical signal provided from the flexible circuit board FCB (see FIG. 2) may be electrically transmitted to the display panel DP through the display pads D-PD. However, the connection method between the display pads D-PD and the flexible circuit board FCB (see FIG. 2) is not limited thereto.

The scan driver SDV may generate scan signals in response to a scan control signal. The scan signals may be applied to the pixels PX through the scan lines SL1 to SLm. The driving chip DDV may generate data voltages corresponding to image signals in response to a data control signal. The data voltages may be applied to the pixels PX through the data lines DL1 to DLn. The emission driver EDV may generate emission signals in response to an emission control signal. The emission signals may be applied to the pixels PX through the emission lines EL1 to ELm.

The pixels PX may receive the data voltages in response to the scan signals. The pixels PX may generate images by emitting light having luminance corresponding to the data voltages in response to the emission signals. An emission time of the pixels PX may be controlled by the emission signals.

FIG. 5 is a plan view of the input sensing layer ISP according to an embodiment of the inventive concept. FIG. 5 briefly illustrates configurations of the input sensing layer ISP disposed on the base layer BS described herein for convenience of explanation.

For example, the input sensing layer ISP may be driven in a mutual-capacitance type. Referring to FIG. 5, the input sensing layer ISP may include first sensing electrodes TEX (TEX1 to TEX6), second sensing electrodes TEY (TEY1 to TEY4), first sensing lines TLX1 to TLX6, second sensing lines TLY1 to TLY4, and sensing pads I-PD. However, embodiments are not limited thereto, and the input sensing layer ISP may be driven in a self-capacitance type.

Each of the first sensing electrodes TEX may extend in the first direction DR1. The first sensing electrodes TEX may be arranged in the second direction DR2. Although six first sensing electrodes TEX1 to TEX6 are illustrated as an example in FIG. 5, the number of first sensing electrodes TEX included in the input sensing layer ISP is not limited thereto. Each first sensing electrode TEX may include first sensing patterns SP1 arranged in the first direction DR1 and first connection patterns BP1 connecting the first sensing patterns SP1 to each other.

Each of the second sensing electrodes TEY may extend in the second direction DR2. The second sensing electrodes TEY may be arranged in the first direction DR1. Although four second sensing electrodes TEY1 to TEY4 are illustrated as an example in FIG. 5, the number of second sensing electrodes TEY included in the input sensing layer ISP is not limited thereto. Each second sensing electrode TEY may include second sensing patterns SP2 arranged in the second direction DR2 and second connection patterns BP2 connecting the second sensing patterns SP2 to each other.

The first sensing electrodes TEX and the second sensing electrodes TEY may be electrically insulated from each other. The input sensing layer ISP may detect an external input through a change in capacitance between the first sensing electrodes TEX and the second sensing electrodes TEY. The first sensing electrodes TEX and the second sensing electrodes TEY may be disposed on an area corresponding to the display area DA (see FIG. 4) of the base layer BS. Thus, the display device EA (see FIG. 2) may display an image through the display area DA (see FIG. 4) and may simultaneously detect an external input applied to the display area DA (see FIG. 4).

The first sensing lines TLX1 to TLX6 may be disposed in the non-display area NDA (see FIG. 4) and electrically connected to the first sensing electrodes TEX1 to TEX6, respectively. A portion of the first sensing lines TLX1 to TLX6 may be disposed at a left side of the non-display area NDA, and a portion of the first sensing lines may be disposed at a right side of the non-display area NDA. For example, the first sensing lines TLX1, TLX3, and TLX5 connected to the first sensing electrodes TEX1, TEX3, and TEX5 arranged in odd rows may be connected to left sides of the first sensing electrodes TEX1, TEX3, and TEX5, respectively, and the first sensing lines TLX2, TLX4, and TLX6 connected to the first sensing electrodes TEX2, TEX4, and TEX6 arranged in even rows may be connected to right sides of the first sensing electrodes TEX2, TEX4, and TEX6, respectively. However, the arrangement of the first sensing lines TLX1 to TLX6 is not limited thereto. For example, all the first sensing lines TLX1 to TLX6 may be disposed at the left side of the non-display area NDA, or all the first sensing lines TLX1 to TLX6 may be disposed at the right side of the non-display area NDA.

Each of the first sensing lines TLX1 to TLX6 may extend from the first base area AA1 to the second base area AA2 via the bending area BA. The first sensing lines TLX1 to TLX6 may be electrically connected to the sensing pads I-PD disposed in the second base area AA2, respectively.

The second sensing lines TLY1 to TLY4 may be disposed in the non-display area NDA (see FIG. 4) and electrically connected to the second sensing electrodes TEY1 to TEY4, respectively. A first portion of the second sensing lines TLY1 to TLY4 may be disposed adjacent to the left side of the non-display area NDA (see FIG. 4), and a second portion may be disposed adjacent to the right side of the non-display area NDA (see FIG. 4). For example, the second sensing lines TLY1 and TLY2 electrically connected to the second sensing electrodes TEY1 and TEY2 disposed at the left side of the second sensing electrodes TEY1 to TEY4 in the first direction DR1 may be disposed adjacent to the left side of the first base area AA1, and the second sensing lines TLY3 and TLY4 electrically connected to the second sensing electrodes TEY3 and TEY4 disposed at the right side may be disposed adjacent to the right side of the first base area AA1. However, the arrangement of the second sensing lines TLY1 to TLY4 is not limited thereto.

Each of the second sensing lines TLY1 to TLY4 may extend from an area adjacent to a lower end portion of the first base area AA1 toward the second base area AA2 via the bending area BA. The second sensing lines TLY1 to TLY4 may be electrically connected to the sensing pads I-PD disposed in the second base area AA2, respectively.

A first portion of the sensing pads I-PD may be disposed on an area adjacent to the left side of the second base area AA2 in the first direction DR1, and a second portion may be disposed on an area adjacent to the right side of the second base area AA2. For example, the sensing pads I-PD may be divided into different groups spaced apart with the display pad area PD-A therebetween. However, the arrangement of the sensing pads I-PD is not limited thereto.

The sensing pads I-PD may be disposed on the same layer as the display pads D-PD (see FIG. 4). The sensing pads I-PD may be disposed on a layer different from that of the first and second sensing lines TLX1 to TLX6 and TLY1 to TLY4 and connected through a contact hole. However, embodiments are not limited thereto, and the sensing pads I-PD may be disposed on a layer different from that of the display pads D-PD (see FIG. 4). For example, the sensing pads I-PD may be provided integrally with the first and second sensing lines TLX1 to TLX6 and TLY1 to TLY4 on the same layer.

The first sensing lines TLX1 to TLX6 and the second sensing lines TLY1 to TLY4 may be disposed above the configurations of the display panel DP (see FIG. 4) on an area of the base layer BS corresponding to the non-display area NDA (see FIG. 4). Thus, the first sensing lines TLX1 to TLX6 and the second sensing lines TLY1 to TLY4 may overlap the configurations of the display panel DP (see FIG. 4) on the bending area BA and the second base area AA2.

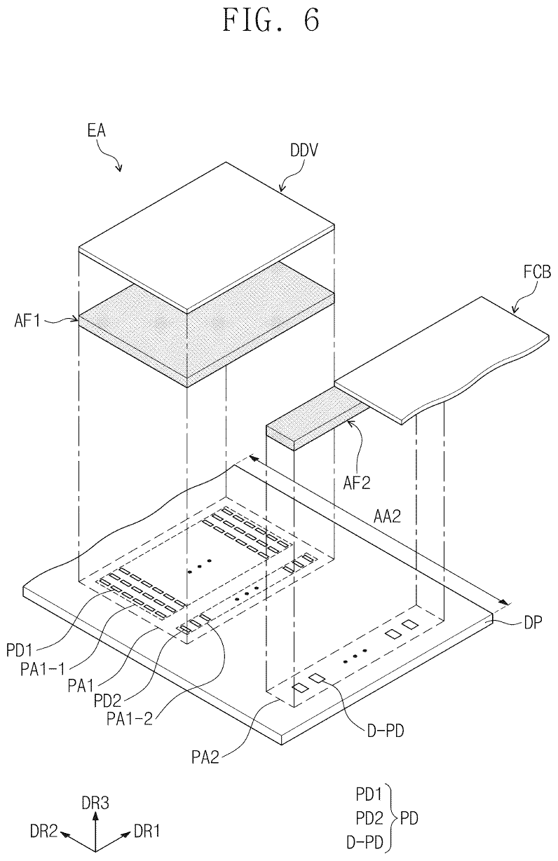

FIG. 6 is a perspective view of the display device EA according to an embodiment of the inventive concept. FIG. 6 briefly illustrates some configurations of the display device EA disposed corresponding to the second base area AA2.

The second base area AA2 may correspond to a portion of the non-display area NDA (see FIG. 4). As illustrated in FIG. 6, in the second base area AA2, the area on which the driving chip DDV is bonded may be defined as the first pad area PA1, and the area on which the flexible circuit board FCB is bonded may be defined as the second pad area PA2.

The driving chip DDV may be bonded to the first pad area PA1. The driving chip DDV may be bonded to the first pad area PA1 through a first conductive adhesive layer AF1. The flexible circuit board FCB may be bonded to the second pad area PA2. The flexible circuit board FCB may be bonded to the second pad area PA2 through a second conductive adhesive layer AF2. The conductive adhesive layer may be provided separately into a first conductive adhesive layer AF1 overlapping the first signal pads PD1 and a second conductive adhesive layer AF2 overlapping the second signal pads PD2. Each of the first conductive adhesive layer AF1 and the second conductive adhesive layer AF2 may be provided as an anisotropic conductive adhesive. For example, each of the first conductive adhesive layer AF1 and the second conductive adhesive layer AF2 may include an adhesive resin and conductive particles dispersed in the adhesive resin.

At least one of the first conductive adhesive layer AF1 or the second conductive adhesive layer AF2 may be omitted. For example, the driving chip DDV and the flexible circuit board FCB may be ultrasonic bonded to the first pad area PA1 and the second pad area PA2, respectively.

The display panel DP may include a plurality of pads PD. The plurality of pads PD may include first signal pads PD1, second signal pads PD2, and display pads D-PD. The first signal pads PD1, the second signal pads PD2, and the display pads D-PD may be pads disposed in a signal transmission path.

The first signal pads PD1 may be disposed to correspond to an output bump of the driving chip DDV and may be input pads that receive signals from the driving chip DDV. The second signal pads PD2 may be disposed to correspond to an input bump of the driving chip DDV and may be output pads that transmit signals to the driving chip DDV. The display pads D-PD may be panel input pads that receive signals from the flexible circuit board FCB.

Each of the first signal pads PD1 may be electrically connected to the pixels PX (see FIG. 4) of the display panel DP through a signal line and may transmit and receive signals to the pixels PX (see FIG. 4). Each of the second signal pads PD2 may be electrically connected to a corresponding display pad D-PD through the signal line, and the display pads D-PD and the second signal pads PD2, which may be electrically connected to each other, may transmit and receive signals.

The first pad area PA1 may include a first sub-pad area PA1-1 and a second sub-pad area PA1-2. The first sub-pad area PA1-1 may be defined as an area on which the first signal pads PD1 are disposed. The second sub-pad area PA1-2 may be defined as an area on which the second signal pads PD2 are disposed.

The first signal pads PD1 may be arranged in the first direction DR1 and the second direction DR2 within the first sub-pad area PA1-1. The first signal pads PD1 arranged in the second direction DR2 may be defined as a pad row. FIG. 6 illustrates an example in which six pad rows are arranged in the second direction DR2. The arrangement of the first signal pads PD1 is not limited, and may be arranged in at least two pad rows in the second direction DR2.

The second signal pads PD2 may be arranged in the first direction DR1 within the second sub-pad area PA1-2. The second signal pads PD2 may be arranged in a pad row. However, the arrangement of the second signal pads PD2 is not limited thereto. For example, the second signal pads PD2 may be arranged in one or more pad rows.

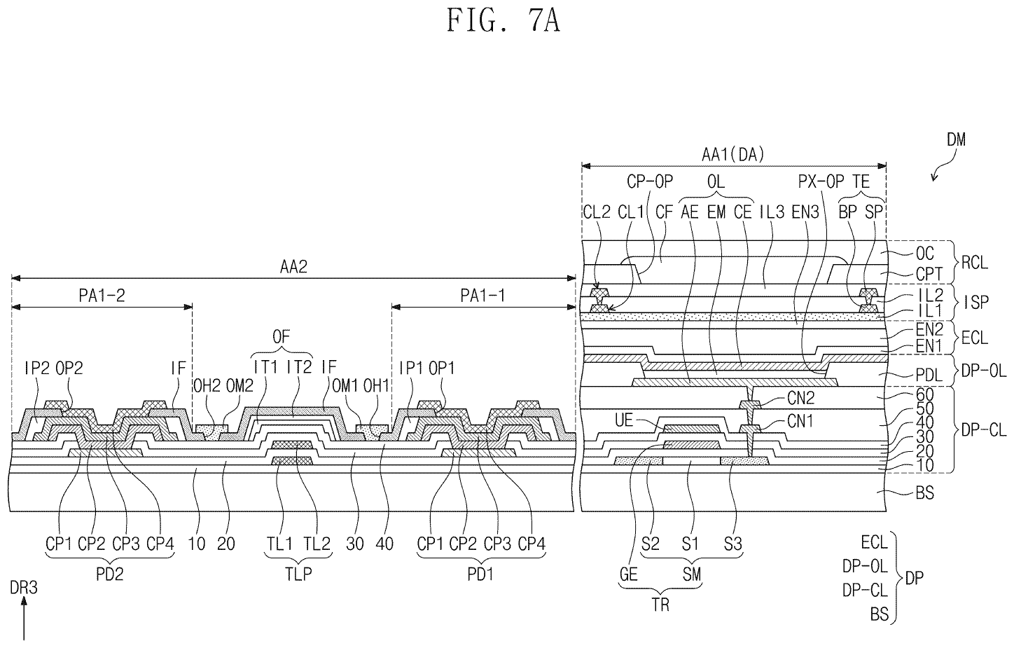

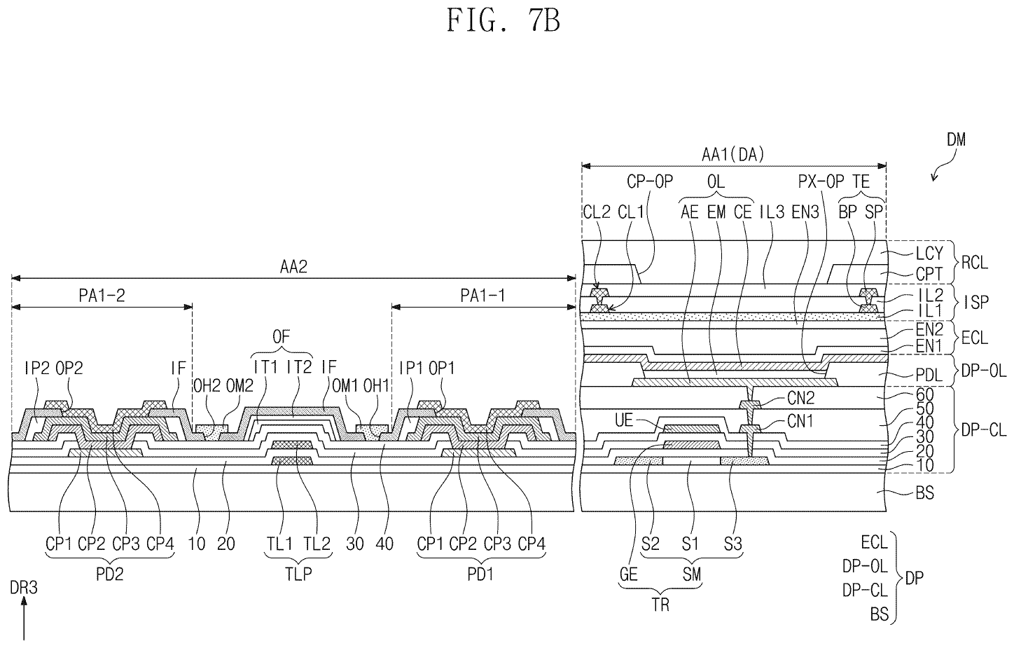

FIG. 7A is a cross-sectional view of the display module DM according to an embodiment of the inventive concept. FIG. 7A illustrates an example of a cross-section corresponding to the first base area AA1 and the second base area AA2 of FIG. 4.

The base layer BS may have insulating properties. The base layer BS may provide a base surface on which components of the display module DM are disposed. The base layer BS may have ductility to enable the bending. As described herein, the base layer BS may include a first base area AA1, a bending area BA (see FIG. 4), and a second base area AA2, and the bending area BA (see FIG. 4) of the base layer BS may be bent to a predetermined curvature.

The circuit layer DP-CL may include insulating layers 10 to 60 disposed on the base layer BS, a transistor TR of the pixel PX (see FIG. 4), an upper electrode UE, and connection electrodes CN1 and CN2. The insulating layers 10 to 60 may include first to sixth insulating layers 10 to 60 sequentially laminated on the base layer BS in the thickness direction. However, embodiments are not limited thereto. For example, the insulating layers 10 to 60 included in the circuit layer DP-CL may be changed depending on a configuration or manufacturing process of the circuit layer DP-CL.

The first insulating layer 10 may be disposed on the base layer BS. The first insulating layer 10 may serve as a barrier layer and/or a buffer layer that may inhibit or prevent foreign substances from being introduced from the outside. The first insulating layer 10 may improve bonding force between the base layer BS and the semiconductor pattern SM and/or the conductive pattern of the circuit layer DP-CL. The first insulating layer 10 may include at least one of a silicon oxide layer or a silicon nitride layer. For example, the first insulating layer 10 may include silicon oxide layers and silicon nitride layers, which may be alternately laminated.

The pixel PX (see FIG. 4) may be disposed on the base layer BS. The pixel PX (see FIG. 4) may be disposed to correspond to the display area DA of the first base area AA1. The pixel PX (see FIG. 4) may include a transistor TR and a light emitting element OL.

The transistor TR may include a semiconductor pattern SM and a gate GE. The semiconductor pattern SM may be disposed on the first insulating layer 10. The semiconductor pattern SM may include a channel S1, a source S2, and a drain S3. The semiconductor pattern SM may include a silicon semiconductor and may include a single crystalline silicon semiconductor, a polysilicon semiconductor, or an amorphous silicon semiconductor. Alternatively, the semiconductor pattern SM may include an oxide semiconductor. The semiconductor pattern SM may be made of various materials as long as the semiconductor pattern SM has semiconductor properties, and is not limited to any embodiment.

The semiconductor pattern SM may include a plurality of regions having different electrical properties depending on whether the semiconductor pattern SM is doped or reduced. For example, the semiconductor pattern SM may include a region having high conductivity due to the doping or reduction of metal oxide, and the region having high conductivity may serve as an electrode or signal wire of the transistor TR. This may correspond to the source S2 and drain S3 of the transistor TR. The semiconductor pattern SM may include an undoped region having relatively low conductivity, which may correspond to the channel S1 (or active) of the transistor TR.

The second insulating layer 20 may be disposed on the first insulating layer 10 to cover the semiconductor pattern SM. The gate GE may be disposed on the second insulating layer 20. The second insulating layer 20 may be disposed between the semiconductor pattern SM and the gate GE of the transistor TR. The gate GE may overlap the channel S1 of the semiconductor pattern SM on a plane. The gate GE may function as a mask in a process of doping the semiconductor pattern SM. The gate GE may include heat-resistant molybdenum (Mo), an alloy containing molybdenum, titanium (Ti), an alloy containing titanium, etc., but is not limited thereto.

A structure of the transistor TR illustrated in FIG. 7A is merely an example, and the source S2 and drain S3 of the transistor TR may be electrodes provided independent of the semiconductor pattern SM. In this case, the source S2 and the drain S3 may be in contact with the semiconductor pattern SM or may be connected to the semiconductor pattern SM through an insulating layer. In addition, the gate GE may be disposed below the semiconductor pattern SM. The transistor TR may be provided in various structures, and is not limited to any embodiment.

The second insulating layer 20 and third to sixth insulating layers 30 to 60 to be described later may include at least one of an inorganic layer or an organic layer. For example, the inorganic layer may include at least one of aluminum oxide, titanium oxide, silicon oxide, silicon oxynitride, zirconium oxide, or hafnium oxide. The organic layer may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyamide-based resin, or a perylene-based resin.

The third insulating layer 30 may be disposed on the second insulating layer 20 and may cover the gate GE. The upper electrode UE may be disposed on the third insulating layer 30. The upper electrode UE may overlap the gate GE on the plane, and the gate GE and the upper electrode UE that overlap each other may form a capacitor.

The fourth insulating layer 40 may be disposed on the third insulating layer 30 and may cover the upper electrode UE. The connection electrodes CN1 and CN2 may include a first connection electrode CN1 and a second connection electrode CN2. The first connection electrode CN1 may be disposed on the fourth insulating layer 40. The fifth insulating layer 50 may be disposed on the fourth insulating layer 40 to cover the first connection electrode CN1. The second connection electrode CN2 may be disposed on the fifth insulating layer 50. The sixth insulating layer 60 may be disposed on the fifth insulating layer 50 to cover the second connection electrode CN2. At least one of the fifth insulating layer 50 or the sixth insulating layer 60 may include an organic layer and may cover stepped portions of the components disposed below the fifth insulating layer 50 and/or the sixth insulating layer 60 to provide a flat top surface.

The first connection electrode CN1 may be electrically connected to the semiconductor pattern SM through a contact hole passing through the second to fourth insulating layers 20 to 40. The second connection electrode CN2 may be electrically connected to the first connection electrode CN1 through a contact hole passing through the fifth insulating layer 50.

Each of the first connection electrode CN1 and the second connection electrode CN2 may include a conductive material. For example, each of the first connection electrode CN1 and the second connection electrode CN2 may include gold, silver, copper, aluminum, platinum, molybdenum, titanium, and alloys thereof. At least one of the first connection electrode CN1 or the second connection electrode CN2 may include conductive layers having a multi-layered structure. For example, at least one of the first connection electrode CN1 or the second connection electrode CN2 may have a three-layer structure of titanium/aluminum/titanium. However, embodiments are not limited thereto.

Alternatively, at least one of the first connection electrode CN1 or the second connection electrode CN2 may be omitted. Alternatively, an additional connection electrode connecting the transistor TR to the light emitting element OL may be further disposed. The electrical connection method between the light emitting element OL and the transistor TR may vary depending on the number of insulating layers disposed between the light emitting element OL and the transistor TR, but is not limited to any embodiment.

The display element layer DP-OL may include a light emitting element OL and a pixel defining layer PDL. The light emitting element OL and the pixel defining layer PDL may be disposed on the sixth insulating layer 60. The light emitting element OL may include a first electrode AE, a second electrode CE disposed on the first electrode AE, and an emission layer EM disposed between the first electrode AE and the second electrode CE.

The pixel defining layer PDL may be transparent or may have a property of absorbing light. For example, the pixel defining layer PDL that absorbs light may include a black coloring agent. The black coloring agent may include a black dye or a black pigment. The black coloring agent may include carbon black, a metal such as chromium, or oxides thereof. The pixel defining layer PDL may correspond to a shielding pattern having light blocking characteristics.

The pixel defining layer PDL may cover a portion of the first electrode AE. For example, a pixel opening PX-OP that exposes a portion of the first electrode AE may be defined in the pixel defining layer PDL.

The first electrode AE may be electrically connected to the second connection electrode CN2 through a contact hole passing through the sixth insulating layer 60. The first electrode AE may be electrically connected to the transistor TR through the first and second connection electrodes CN1 and CN2.

The first electrode AE may be an anode or a cathode. The first electrode AE may be a transparent electrode, a translucent electrode, or a reflective electrode. The first electrode AE may include a reflective layer made of Ag, Mg, Al, Pt, Pd, Au, Ni, Nd, Ir, Cr, or a compound thereof, and a transparent or translucent electrode layer disposed on the reflective layer. The transparent or translucent electrode layer include at least one selected from the group of indium tin oxide (ITO), indium zinc oxide (IZO), indium gallium zinc oxide (IGZO), zinc oxide (ZnOx) or indium oxide (In₂O₃), and aluminum doped zinc oxide (AZO). For example, the first electrode AE may include a three-layer structure of ITO/Ag/ITO, but is not limited thereto.

The emission layer EM may include an organic light emitting material, an inorganic light emitting material, an organic-inorganic light emitting material, a quantum dot, a quantum rod, a micro LED, or a nano LED. For example, the emission layer EM may include a fluorescent material or a phosphorescent material. The emission layer EM may be disposed within the pixel opening PX-OP defined in the pixel defining layer PDL. Alternatively, the emission layer EM may be provided as a common layer.

The second electrode CE may be a cathode or an anode, but embodiments are not limited thereto. For example, when the first electrode AE is the anode, the second electrode CE may be the cathode, and when the first electrode AE is the cathode, the second electrode CE may be the anode. The second electrode CE may be provided as a common layer. The second electrode CE may be referred to as a common electrode. For example, the second electrode CE may include at least one selected from Ag, Mg, Cu, Al, Pt, Pd, Au, Ni, Nd, Ir, Cr, Li, Ca, LiF, Mo, Ti, W, In, Sn, or Zn, two or more compounds selected from the materials described herein, or a mixture of two or more selected from the materials or oxides described herein.

A hole transport region may be defined between the first electrode AE and the emission layer EM. The hole transport region may include at least one of a hole transport layer, a hole injection layer, and an electron blocking layer. The hole transport region may include known hole injection and/or hole transport materials. An electron transport region may be defined between the emission layer EM and the second electrode CE. The electron transport region may include at least one of an electron transport layer, an electron injection layer, or a hole blocking layer. The electron transport region may include known electron injecting and/or electron transport materials.

The encapsulation layer ECL may be disposed on the display element layer DP-OL. The encapsulation layer ECL may be disposed on the light emitting element OL and the pixel defining layer PDL to seal the light emitting element OL. The encapsulation layer ECL may include at least one of an inorganic encapsulation layer or an organic encapsulation layer. For example, the encapsulation layer ECL may include a first inorganic encapsulation layer EN1, an organic encapsulation layer EN2, and a second inorganic encapsulation layer EN3, which may be sequentially laminated. However, the configuration of the encapsulation layer ECL is not limited thereto as long as the encapsulation layer ECL seals the light emitting element OL.

The first and second inorganic encapsulation layers EN1 and EN3 may protect the light emitting element OL from moisture or oxygen introduced from the outside. The organic encapsulation layer EN2 may inhibit or prevent foreign substances from being introduced into the light emitting element OL and may cover stepped portions of components disposed under the organic encapsulation layer EN2. For example, each of the first and second inorganic encapsulation layers EN1 and EN3 may include at least one of silicon nitride, silicon oxynitride, silicon oxide, titanium oxide, or aluminum oxide. The organic encapsulation layer EN2 may include an acrylic-based organic material. However, this is merely an example, and the materials included in the first and second inorganic encapsulation layers EN1 and EN3 and the organic encapsulation layer EN2 are not limited thereto.

The input sensing layer ISP may be disposed on the display panel DP. The input sensing layer ISP may include a base insulating layer IL1, a first sub-insulating layer IL2, a second sub-insulating layer IL3, a first sensing conductive layer CL1, and a second sensing conductive layer CL2. Variations of the input sensing layer ISP described herein may be applied to each configuration of the input sensing layer ISP.

The base insulating layer IL1 may be in contact with the uppermost layer of the encapsulation layer ECL. For example, the base insulating layer IL1 may be in contact with the second inorganic encapsulation layer EN3 of the encapsulation layer ECL. The base insulating layer IL1 of the input sensing layer ISP may be disposed directly on the base surface provided by the encapsulation layer ECL. However, this is merely an example, and embodiments are not limited thereto. For example, the base insulating layer IL1 may be omitted, and the first sensing conductive layer CL1 of the input sensing layer ISP may be in contact with the encapsulation layer ECL.

The first sensing conductive layer CL1 may be disposed on the base insulating layer IL1, and the second sensing conductive layer CL2 may be disposed on the first sub-insulating layer IL2. The first sensing conductive layer CL1 and the second sensing conductive layer CL2 may form a sensing electrode TE. The sensing electrode TE may correspond to any one of the first and second sensing electrodes TEX and TEY (see FIG. 5). For example, the first sensing conductive layer CL1 may include a connection pattern BP of the sensing electrode TE, and the second sensing conductive layer CL2 may include a sensing pattern SP of the sensing electrode TE. Alternatively, the first sensing conductive layer CL1 may include a sensing pattern SP, and the second sensing conductive layer CL2 may include a connection pattern BP.

The connection pattern BP may correspond to the first connection pattern BP1 (see FIG. 5) or the second connection pattern BP2 (see FIG. 5), and the sensing pattern SP may correspond to the first sensing pattern SP1 (see FIG. 5) or the second sensing pattern SP2 (see FIG. 5). The connection pattern BP may be disposed on a layer different from that of the sensing pattern SP and may be connected through a contact hole passing through the first sub-insulating layer IL2. However, embodiments are not limited thereto, and the connection pattern BP and the sensing pattern SP may be disposed on the same layer and provided to be integrated with each other.

The sensing electrode TE may be a mesh-shaped pattern and may be disposed to correspond to an area on which the pixel defining layer PDL is disposed. However, embodiments are not limited thereto, and the sensing electrode TE may be provided as a single-shaped pattern that overlaps the light emitting element OL. In this case, the sensing electrode TE may include a transparent conductive material.

An optical layer RCL may be disposed on the input sensing layer ISP. The optical layer RCL may include at least one of a pigment or a dye. The optical layer RCL may include an optical pattern part CPT, a filter part CF, and an over-layer OC.

The optical pattern part CPT may not overlap the emission layer EM, and a pattern opening CP-OP may be defined in the optical pattern part CPT. A material forming the optical pattern part CPT may absorb light. A material forming the optical pattern part CPT is not particularly limited. The optical pattern part CPT may have a black color, and the optical pattern part CPT may include a black coloring agent. The black coloring agent may include a black dye and a black pigment. For example, the black coloring agent may include carbon black, a metal such as chromium, or oxides thereof.

The filter part CF may be disposed to fill the pattern opening CP-OP. The filter part CF may overlap the emission layer EM. The filter part CF may contain a pigment or a dye. The filter part CF may be provided in plurality, and each of the plurality of filter parts CF may be a red, green, or blue filter. The red filter may transmit red light, the green filter may transmit green light, and the blue filter may transmit blue light. The dye and/or pigment included in the filter part CF may be a material that transmits only light having a specific wavelength region in light emitted from the display element layer DP-OL. Thus, the filter part CF may improve display quality and light efficiency of the display device EA (see FIG. 2).

The over-layer OC may be disposed on the optical pattern part CPT and the filter part CF. The over-layer OC may be a planarization layer. The over-layer OC may cover a stepped portion between the optical pattern part CPT and the filter part CF, which may be disposed below the over-layer OC and may provide a flat surface. A top surface of the over-layer OC may be flat. The over-layer OC may include an organic material.

The first insulating layer 10 and the second insulating layer 20 may extend from the first base area AA1 on the base layer BS and may be disposed in the second base area AA2. The first signal pad PD1 and the second signal pad PD2 may be disposed on the second insulating layer 20. The first signal pad PD1 may be disposed in the first sub-pad area PA1-1, and the second signal pad PD2 may be disposed in the second sub-pad area PA1-2. The first signal pad PD1 may be disposed closer to the display area DA within the second base area AA2 than the second signal pad PD2. In a direction perpendicular to the thickness direction DR3, the second signal pad PD2 may be spaced apart from the first base area AA1 with the first signal pad PD1 therebetween. In the direction perpendicular to the thickness direction DR3, the second signal pad PD2 may be spaced apart from the display area DA with the first signal pad PD1 therebetween.

Each of the first and second signal pads PD1 and PD2 may include a plurality of conductive patterns CP1, CP2, CP3, and CP4 arranged in the thickness direction DR3. The first conductive pattern CP1 of each of the first signal pad PD1 and the second signal pad PD2 may be disposed on the second insulating layer 20.

The first conductive patterns CP1 of the first signal pad PD1 and the second signal pad PD2 may be formed through the same process as the gate GE of the transistor TR. For example, after forming a conductive layer on the second insulating layer 20 through a deposition process such as sputtering or chemical vapor deposition, the conductive layer may be patterned to form the first conductive patterns CP1 the first and second signal pads PD1 and PD2 and the gate GE. The first conductive patterns CP1 of the first and second signal pads PD1 and PD2 may be disposed on the same layer as the gate GE of the transistor TR and may include the same material.

The third insulating layer 30 and the fourth insulating layer 40 may extend from the first base area AA1 and be disposed in the second base area AA2. A through-hole exposing the upper surfaces of the first conductive patterns CP1 of the first signal pad PD1 and the second signal pad PD2 will be defined in the third insulating layer 30 and the fourth insulating layer 40. The third insulating layer 30 and the fourth insulating layer 40 are formed by sequentially depositing the insulating layers in the first base area AA1 and the second base area AA2 and then performing etching so that a portion of a top surface of the first conductive pattern CP1 of each of the first and second signal pads PD1 and PD2 is exposed.

As illustrated in FIG. 7A, at least a portion of the insulating layers disposed in the first base area AA1 may be disposed in the second base area AA2, and a laminated structure of the insulating layers disposed in the second base area AA2 is not particularly limited as being illustrated.

The second conductive patterns CP2 of the first signal pad PD1 and the second signal pad PD2 may be disposed on exposed upper surfaces of the first conductive patterns CP1, respectively. The second conductive patterns CP2 may be in contact with the first conductive patterns CP1, respectively. A portion of the second conductive patterns CP2 may be disposed on the fourth insulating layer 40. For example, a portion of the second conductive patterns CP2 may cover inner surfaces of the third and fourth insulating layers 30 and 40 exposed by the through-hole and may be disposed on the fourth insulating layer 40.

The second conductive patterns CP2 of the first signal pad PD1 and the second signal pad PD2 may be formed through the same process as any one of the conductive electrodes of the circuit layer DP-CL. For example, the second conductive patterns CP2 of the first signal pad PD1 and the second signal pad PD2 may be formed through the same process as the first connection electrode CN1. After forming a conductive layer on the fourth insulating layer 40 through a deposition process such as sputtering or chemical vapor deposition, the conductive layer may be patterned to form the first connection electrode CN1 and the second conductive patterns CP2 of the first and second signal pads PD1 and PD2. The second conductive patterns CP2 of the first and second signal pads PD1 and PD2 may be disposed on the same layer as the first connection electrode CN1 and may include the same material.

The third conductive patterns CP3 of the first signal pad PD1 and the second signal pad PD2 may be disposed on the second conductive patterns CP2, respectively. The third conductive patterns CP3 may be in contact with the second conductive patterns CP2, respectively. The third conductive patterns CP3 of the first and second signal pads PD1 and PD2 may be formed through the same process as a conductive electrode of the circuit layer DP-CL. For example, the third conductive patterns CP3 of the first signal pad PD1 and the second signal pad PD2 may be formed through the same process as the second connection electrode CN2.

The fifth insulating layer 50 disposed below the second connection electrode CN2 may be opened to correspond to an area on which the first and second signal pads PD1 and PD2 are disposed. That is, the fifth insulating layer 50 may not be disposed on the second conductive patterns CP2 of the first and second signal pads PD1 and PD2, but a portion of the conductive layer deposited on the fifth insulating layer 50 may be in contact with the second conductive patterns CP2. After forming a conductive layer on the fifth insulating layer 50 through a deposition process such as sputtering or chemical vapor deposition, the conductive layer may be patterned to form the second connection electrode CN2 and the third conductive patterns CP3 of the first and second signal pads PD1 and PD2. The third conductive patterns CP3 may be formed through the same process as the second connection electrode CN2 and may include the same material.

First and second insulating patterns IP1 and IP2 may be disposed in the second base area AA2. The first insulating pattern IP1 may be disposed to correspond to the first signal pad PD1 and may cover an edge portion of the first signal pad PD1. Specifically, the first insulating pattern IP1 may cover an edge portion of the third conductive pattern CP3 of the first signal pad PD1. The second insulating pattern IP2 may be disposed to correspond to the second signal pad PD2 and may cover an edge portion of the second signal pad PD2. Specifically, the second insulating pattern IP2 may cover an edge portion of the third conductive pattern CP3 of the second signal pad PD2. For example, the edge portions of the third conductive patterns CP3 of the first and second signal pads PD1 and PD2 may be disposed on the fourth insulating layer 40, and the first and second insulating patterns IP1 and IP2 may be disposed on the fourth insulating layer 40 to cover the edge portions of the third conductive patterns CP3, respectively.

The first and second insulating patterns IP1 and IP2 may be formed simultaneously through the same process as at least one of the insulating layers included in the circuit layer DP-CL. For example, the first and second insulating patterns IP1 and IP2 may be formed simultaneously during the formation of the sixth insulating layer 60. After forming an insulating layer on the fifth insulating layer 50 and the third conductive patterns CP3 of the first and second signal pads PD1 and PD2 through a process such as deposition, coating, or printing, the insulating layer may be patterned to form the sixth insulating layer 60 and the first and second insulating patterns IP1 and IP2. The first and second insulating patterns IP1 and IP2 may include the same material as the sixth insulating layer 60. The first and second insulating patterns IP1 and IP2 are provided by etching or patterning the insulating layer to cover the edge portions of the third conductive patterns CP3 of the first and second signal pads PD1 and PD2, respectively.

Each of the first and second insulating patterns IP1 and IP2 may include an organic material. For example, each of the first and second insulating patterns IP1 and IP2 may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyamide-based resin, or a perylene-based resin. However, this is merely an example, and the materials included in the first and second insulating patterns IP1 and IP2 are not limited thereto.

The base insulating layer IL1 of the input sensing layer ISP may extend from the first base area AA1 and be disposed in the second base area AA2. The base insulating layer IL1 disposed in the second base area AA2 may be defined as an insulating film IF. That is, the base insulating layer IL1 disposed in the first base area AA1 and the insulating film IF disposed in the second base area AA2 may be integrated with each other.

However, embodiments are not limited thereto, and both the base insulating layer IL1 and the first sub-insulating layer IL2 of the input sensing layer ISP may extend from the first base area AA1 and be disposed in the second base area AA2. In this case, the base insulating layer IL1 and the first sub-insulating layer IL2, which may be laminated in the second base area AA2, may correspond to the insulating film IF.

The insulating film IF may be formed at the same time as the forming process of the insulating layer (e.g., the base insulating layer IL1 or the first sub-insulating layer IL2) included in the input sensing layer ISP. For example, after depositing the insulating layer in the first and second base areas AA1 and AA2 through the deposition process such as chemical vapor deposition, the insulating layer may be etched or patterned to form the base insulating layer IL1 (or the first sub-insulating layer IL2) and the insulating film IF.

The insulating film IF may contain an inorganic material. The insulating film IF may inhibit or prevent moisture or oxygen from being introduced. For example, the insulating film IF may include at least one of aluminum oxide, titanium oxide, silicon oxide, silicon oxynitride, zirconium oxide, or hafnium oxide. However, this is merely an example, and the material included in the insulating film IF is not limited thereto.

The insulating film IF may be disposed on the first and second insulating patterns IP1 and IP2. The insulating film IF may be disposed to cover the first and second insulating patterns IP1 and IP2. In the thickness direction DR3, the insulating film IF may overlap the edge portions of the third conductive pattern CP3 of the first and second signal pads PD1 and PD2.

A plurality of openings OP1, OP2, OH1, and OH2 may be defined in the insulating film IF. The first pad opening OP1 of the insulating film IF may be defined to correspond to the first sub-pad area PA1-1, and the second pad opening OP2 of the insulating film IF may be defined to correspond to the second sub-pad area PA1-2. The first pad opening OP1 may expose the first signal pad PD1, and the second pad opening OP2 may expose the second signal pad PD2.

The first insulating opening OH1 of the insulating film IF may be defined adjacent to the first signal pad PD1, and the second insulating opening OH2 of the insulating film IF may be defined adjacent to the second signal pad PD2. The first insulating opening OH1 may be defined between the first pad opening OP1 and the second pad opening OP2. The second insulating opening OH2 may be defined between the first pad opening OP1 and the second pad opening OP2. The first insulating opening OH1 may be defined between the first signal pad PD1 and the auxiliary circuit part TLP. The second insulating opening OH2 may be defined between the second signal pad PD2 and the auxiliary circuit part TLP. The first and second insulating openings OH1 and OH2 may be defined to be spaced apart from each other with an auxiliary circuit part TLP therebetween.

The fourth conductive patterns CP4 of the first signal pad PD1 and the second signal pad PD2 may be disposed on top surfaces of the third conductive patterns CP3 exposed from the insulating film IF, respectively. The fourth conductive patterns CP4 may be in contact with the third conductive patterns CP3. The fourth conductive pattern CP4 of the first signal pad PD1 may be exposed through the first pad opening OP1. The fourth conductive pattern CP4 of the second signal pad PD2 may be exposed through the second pad opening OP2. A portion of the fourth conductive patterns CP4 of the first and second signal pads PD1 and PD2 may be disposed on the insulating film IF. For example, the fourth conductive pattern CP4 of the first signal pad PD1 may be disposed on the insulating film IF overlapping the third conductive pattern CP3 of the first signal pad PD1. The fourth conductive pattern CP4 of the second signal pad PD2 may be disposed on the insulating film IF overlapping the third conductive pattern CP3 of the second signal pad PD2. However, this is merely an example, and embodiments are not limited thereto.

The fourth conductive patterns CP4 of the first signal pad PD1 and the second signal pad PD2 may be formed through the same process as any one of the conductive layers of the input sensing layer ISP. For example, the fourth conductive patterns CP4 of the first and second signal pads PD1 and PD2 may be formed through the same process as the first sensing conductive layer CL1 or the second sensing conductive layer CL2. The fourth conductive patterns CP4 may include the same material as the first sensing conductive layer CL1 or the second sensing conductive layer CL2. For example, the base insulating layer IL1 and the insulating film IF may be formed, and the conductive layer may be formed thereon through the deposition process such as sputtering or chemical vapor deposition, and then, the conductive layer may be patterned to form the first sensing conductive layer CL1 and the fourth conductive patterns CP4 of the first and second signal pads PD1 and PD2.

An auxiliary circuit part TLP may be disposed in the second base area AA2. In the direction perpendicular to the thickness direction DR3, the auxiliary circuit part TLP may be disposed between the first signal pad PD1 and the second signal pad PD2. The auxiliary circuit part TLP may be disposed in the second base area AA2 of the non-display area NDA. The auxiliary circuit part TLP may be configured to inspect the pixel PX (see FIG. 4). For example, the auxiliary circuit part TLP may be configured to inspect whether the pixel PX (see FIG. 4) is operating normally before attaching the flexible circuit board FCB during the process of manufacturing the display device EA (see FIG. 2). After the manufacturing process is completed, the auxiliary circuit part TLP may remain in the display device EA (see FIG. 2). The auxiliary circuit part TLP may include first and second auxiliary lines TL1 and TL2. The first and second auxiliary lines TL1 and TL2 may be used for inspecting lighting of the pixel PX (see FIG. 4). However, embodiments are not limited thereto, and the auxiliary circuit part TLP may include three or more auxiliary lines disposed on different layers. During the process of manufacturing the display device EA (see FIG. 2), each of the first and second auxiliary lines TL1 and TL2 may be electrically connected to at least one signal line SL1 to SLm, DL1 to DLn, EL1 to ELm, CSL1, CSL2, and PL (see FIG. 4) and may inspect whether the pixel PX (see FIG. 4) is operating normally.

For example, the first and second auxiliary lines TL1 and TL2 may be formed during the process of forming the transistor TR within the circuit layer DP-CL. The first auxiliary line TL1 may be formed during the process of forming the semiconductor pattern SM. In the process of forming the semiconductor pattern SM on the first insulating layer 10, a first auxiliary line TL1 may be formed. The second auxiliary line TL2 may be formed in the process of forming the gate GE of the transistor TR. In the process of forming the gate GE on the second insulating layer 20, a second auxiliary line TL2 may be formed. However, the process of forming the first and second auxiliary lines TL1 and TL2 is not limited thereto, and each of the first and second auxiliary lines TL1 and TL2 may be formed at the same time during the process of forming any one of the signal lines SL1 to SLm, DL1 to DLn, EL1 to ELm, CSL1, CSL2, and PL (see FIG. 4).

At least one of the first and second auxiliary lines TL1 and TL2 may be disposed on the same layer as at least one of the first and second signal pads PD1 and PD2. For example, the second auxiliary line TL2 may be disposed on the same layer as the first conductive patterns CP1 of the first and second signal pads PD1 and PD2. However, the arrangement position of the auxiliary circuit part TLP is not limited to any embodiment. That is, the auxiliary circuit part TLP may be disposed on any one of the inorganic insulating layers of the circuit layer DP-CL. For example, the inorganic insulating layers may be the first to fourth insulating layers 10 to 40.

In the second base area AA2, the organic protective layer OF may be disposed on the auxiliary circuit part TLP. The organic protective layer OF may not overlap the first and second signal pads PD1 and PD2. The organic protective layer OF may overlap the auxiliary circuit part TLP. The organic protective layer OF may be disposed on an area overlapping the auxiliary circuit part TLP. The organic protective layer OF may protect the auxiliary circuit part TLP. In the thickness direction DR3, the organic protective layer OF may be disposed between the auxiliary circuit part TLP and the insulating film IF. For example, the insulating film IF may be disposed on the organic protective layer OF. The organic protective layer OF may include an organic material and may be a layer that protects components disposed below the organic protective layer OF.

In the second base area AA2, the insulating film IF may be disposed on the organic protective layer OF. The insulating film IF may be disposed in the second base area AA2 to cover the organic protective layer OF. For example, the insulating film IF may be disposed on the organic protective layer OF and may include portions disposed on an area of the fourth insulating layer 40 adjacent to the organic protective layer OF. The insulating film IF may have first and second insulating openings OH1 and OH2 defined at positions adjacent the organic protective layer OF, and the first and second insulating openings OH1 and OH2 may not expose a portion of the organic protective layer OF.

An organic protective layer containing an organic material may be vulnerable to high temperature/high humidity conditions, and when the organic protective layer is exposed to high temperature/high humidity conditions, the insulating film disposed on the organic protective layer may also be lifted. In the insulating film without the first and second insulating openings, moisture and/or oxygen may be introduced into a gap caused by the lifting of the insulating film, which may lead to corrosion of the first and second signal pads adjacent to the insulating film. In an embodiment, the insulating film IF may have first and second insulating openings OH1 and OH2 defined at positions adjacent to the first and second signal pads PD1 and PD2. Thus, even if the insulating film IF is lifted, a gap may not be generated at the position adjacent to the first and second signal pads PD1 and PD2. Thus, corrosion of the first and second signal pads PD1 and PD2 may be inhibited or prevented, and the display device EA (see FIG. 2) according to an embodiment may exhibit improved reliability.

The organic protective layer OF may include first and second organic patterns IT1 and IT2. The first organic pattern IT1 may be disposed on the auxiliary circuit part TLP, and the second organic pattern IT2 may be disposed on the first organic pattern IT1. The first and second organic patterns IT1 and IT2 may be disposed on an area that overlaps the auxiliary circuit part TLP. Each of the first and second organic patterns IT1 and IT2 may not overlap the first and second insulating openings OH1 and OH2. Each of the first and second organic patterns IT1 and IT2 may not overlap the first and second signal pads PD1 and PD2. For example, the first and second organic patterns IT1 and IT2 may be disposed on an area of the fourth insulating layer 40 that overlaps the auxiliary circuit portion TLP.

For example, the first organic pattern IT1 may be formed at the same time during the formation of the fifth insulating layer 50. After forming the insulating layer on the fourth insulating layer 40 through a process such as deposition, coating, or printing, the insulating layer may be patterned to form the fifth insulating layer 50 and the first organic pattern IT1. Thereafter, the second organic pattern IT2 may be formed on the first organic pattern IT1.

For example, the second organic pattern IT2 may be formed at the same time during the formation of the sixth insulating layer 60. After forming an insulating layer on the fifth insulating layer 50 and the third conductive patterns CP3 of the first and second signal pads PD1 and PD2 through a process such as deposition, coating, or printing, the insulating layer may be patterned to form the sixth insulating layer 60, the first and second insulating patterns IP1 and IP2, and the second organic pattern IT2. The second organic pattern IT2 may include the same material as the sixth insulating layer 60.

First and second organic films OM1 and OM2 may be disposed on the insulating film IF. The first and second organic films OM1 and OM2 may be disposed in the second base area AA2. The first organic film OM1 may be disposed to fill at least a portion of the first insulating opening OH1 of the insulating film IF. The first organic film OM1 may be in contact with a component or layer disposed below the insulating film IF through the first insulating opening OH1. For example, The first organic film OM1 may be in contact with the fourth insulating layer 40 disposed below the insulating film IF through the first insulating opening OH1. In the thickness direction DR3, the first organic film OM1 may overlap an edge portion of the insulating film IF defining the first insulating opening OH1. The first organic film OM1 may be disposed to cover an edge portion of the insulating film IF defining the first insulating opening OH1. The first organic film OM1 may not overlap the first and second signal pads PD1 and PD2. For example, the first organic film OM1 may be disposed apart from the first and second signal pads PD1 and PD2.

In the direction perpendicular to the thickness direction DR3, the first organic film OM1 and the second organic film OM2 may be spaced apart from each other with the organic protective layer OF therebetween. The first organic film OM1 and the second organic film OM2 may not overlap the auxiliary circuit part TLP.

The second organic film OM2 may be disposed to fill at least a portion of the second insulating opening OH2 of the insulating film IF. The second organic film OM2 may be in contact with a component (e.g., the fourth insulating layer 40) disposed below the insulating film IF through the second insulating opening OH2. In the thickness direction DR3, the second organic film OM2 may overlap an edge portion of the insulating film IF defining the second insulating opening OH2. The second organic film OM2 may be disposed to cover an edge portion of the insulating film IF that defines the second insulating opening OH2. The second organic film OM2 may not overlap the first and second signal pads PD1 and PD2. For example, the second organic film OM2 may be disposed apart from the first and second signal pads PD1 and PD2.

The first and second insulating openings OH1 and OH2 may be provided in a rectangular shape on the plane. Area where the first and second insulating openings OH1 and OH2 are disposed may correspond to an area that is vulnerable to cracks, which may be due to stress occurring when the display panel DP is bent. In an embodiment, the first and second organic films OM1 and OM2 may be disposed to fill at least a portion of the first and second insulating openings OH1 and OH2, respectively, and may inhibit or prevent cracks from occurring when the display panel DP is bent. The first and second organic films OM1 and OM2 may be disposed to fill at least a portion of the first and second insulating openings OH1 and OH2, respectively, and thus, an area that may be vulnerable to crack generation in the insulating film IF may be disposed on a neutral plane to inhibit or prevent the occurrence of the cracks in the insulating film IF.

In addition, the first and second organic films OM1 and OM2 may serve as supports, which may inhibit or prevent the occurrence of the cracks due to the bending of the display panel DP. The display panel DP may be partially bent due to a pressure applied during the bonding of the driving chip DDV (see FIG. 6). Cracks may occur due to the bending of the display panel DP. The first and second organic films OM1 and OM2 may serve as supports, which may buffer the pressure applied during the bonding. The first and second organic films OM1 and OM2 may alleviate stress occurring due to the bending of the display panel DP. For example, the first and second organic films OM1 and OM2 may alleviate stress in the insulating film IF occurring during a bending moment of the display panel DP while the bending area BA is bent. The first and second organic films OM1 and OM2 may increase a rigidity of the non-display area of the second base area AA2. For example, a rigidity of the insulating film IF may be increased due to the first and second organic films OM1 and OM2. For example, the insulating film IF, including the first and second organic films OM1 and OM2, may have improved resistance to a bending stress of the display panel DP while the bending area BA is bent. Thus, the display device EA (see FIG. 2) including the first and second organic films OM1 and OM2 may inhibit or prevent cracks in the insulating film IF.

The first and second organic films OM1 and OM2 may be disposed on the light emitting element OL and may include the same organic material as a member made of an organic material. Each of the first and second organic films OM1 and OM2 may include the same organic material as the organic material forming the input sensing layer ISP, the encapsulation layer ECL, or the optical layer RCL. Specifically, each of the first and second organic films OM1 and OM2 may include the same organic material as the sub-insulating layers IL2 and IL3 of the input sensing layer ISP, the organic encapsulation layer EN2 of the encapsulation layer ECL, and the over-layer OC of the optical layer RCL. Thus, manufacturing efficiency of the display device EA (FIG. 2) may be improved.

For example, the first sub-insulating layer IL2 and the first and second organic films OM1 and OM2, or the second sub-insulating layer IL3 and the first and second organic films OM1 and OM2 may be made of the same organic material. The first and second organic films OM1 and OM2 may be formed at the same time during the formation of the first sub-insulating layer IL2 or the second sub-insulating layer IL3. The first and second organic films OM1 and OM2 may be formed at the same time with the first sub-insulating layer IL2 or the second sub-insulating layer IL3 and may include the same organic material as the first sub-insulating layer IL2 or the second sub-insulating layer IL3. For example, after depositing the insulating layer in the first and second base areas AA1 and AA2 through the deposition process such as chemical vapor deposition, the insulating layer may be etched or patterned to form the first sub-insulating layer IL2 (or the second sub-insulating layer IL3), the first organic film OM1, and the second organic film OM2.

Alternatively, each of the first and second organic films OM1 and OM2 may be made of the same organic material as the over-layer OC. The first and second organic films OM1 and OM2 may be made at the same time as the over-layer OC. The first and second organic films OM1 and OM2 may be formed simultaneously with the over-layer OC and may include the same organic material as the over-layer OC. For example, after depositing the organic layer in the first and second base areas AA1 and AA2 through the deposition process such as chemical vapor deposition, the organic layer may be etched or patterned to form the over-layer OC, the first organic film OM1, and the second organic film OM2.

Alternatively, each of the first and second organic films OM1 and OM2 may be made of the same organic material as the organic encapsulation layer EN2. The first and second organic films OM1 and OM2 may be formed simultaneously during the formation of the organic encapsulation layer EN2.

The first and second organic films OM1 and OM2 may be formed simultaneously with the organic encapsulation layer EN2. The first and second organic films OM1 and OM2 may include the same organic material as the organic encapsulation layer EN2. For example, after depositing the organic layer in the first and second base areas AA1 and AA2 through the deposition process such as chemical vapor deposition, the organic layer may be etched or patterned to form the organic encapsulation layer EN2, the first organic film OM1, and the second organic film OM2.

FIG. 7B is a cross-sectional view of a display module DM according to another embodiment of the inventive concept. Hereinafter, in the description of FIG. 7B, repeated descriptions of contents that overlap those described with reference to FIGS. 1 to 7A may be omitted or simplified.

Referring to FIG. 7B, an optical layer RCL includes an optical pattern part CPT and a sub-optical layer LCY. The sub-optical layer LCY may fill a pattern opening CP-OP of the optical pattern part CPT and may be disposed on the optical pattern part CPT. The sub-optical layer LCY may cover the optical pattern part CPT. The sub-optical layer LCY may be a planarization layer.

The sub-optical layer LCY may include a pigment or a dye. The sub-optical layer LCY may be a layer that selectively transmits light emitted from a display panel DP. The dye and pigment included in the sub-optical layer LCY may be materials that transmit only light having a specific wavelength region in light emitted from a display element layer DP-OL. Thus, the sub-optical layer LCY may improve display quality and light efficiency of the display device EA (see FIG. 2).

Each of first and second organic films OM1 and OM2 may include the same organic material as the sub-optical layer LCY. Each of the first and second organic films OM1 and OM2 may be formed at the same time as the sub-optical layer LCY. For example, the first and second organic films OM1 and OM2 may be formed simultaneously with the sub-optical layer LCY and may include the same organic material as the sub-optical layer LCY. For example, after depositing the organic layer in the first and second base areas AA1 and AA2 through the deposition process such as chemical vapor deposition, the organic layer may be etched or patterned to form the sub-optical layer LCY, the first organic film OM1, and the second organic film OM2.

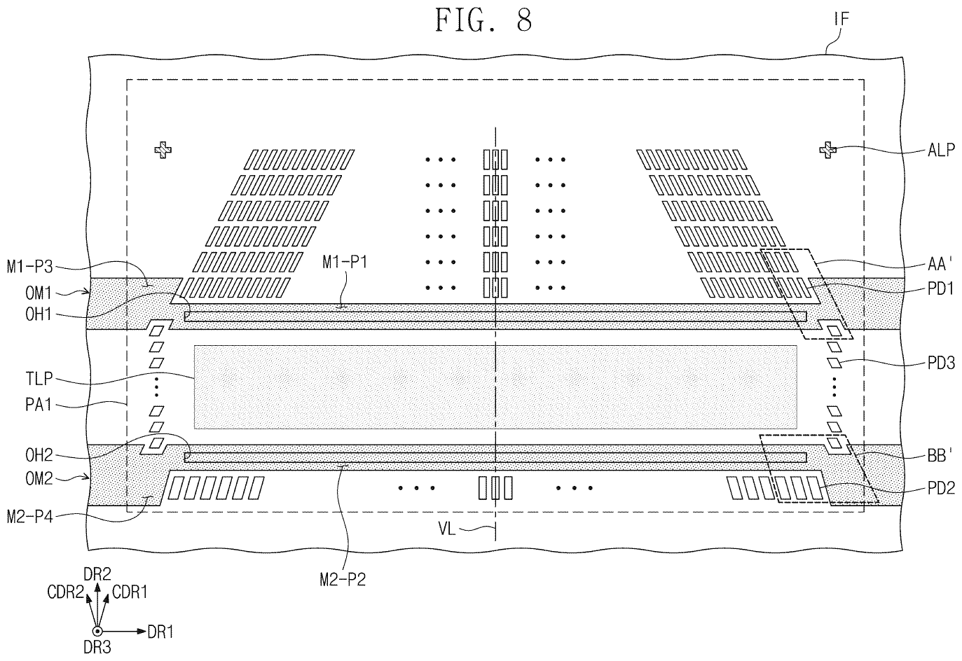

FIG. 8 is a plan view illustrating a configuration of the display panel DP disposed in the second base area AA2 of FIG. 6 and FIGS. 7A and 7B. FIG. 8 is an enlarged plan view of the first pad area PA1 of FIG. 6. In FIG. 8, some components of the display panel DP may be omitted for convenience of explanation.

Referring to FIG. 8, the first and second signal pads PD1 and PD2 may be disposed in the first pad area PA1. The first signal pads PD1 may be disposed in two or more rows, and each row may be parallel to the first direction DR1. FIG. 8 illustrates an example in which the first signal pads PD1 are disposed in six rows.

The first signal pads PD1 disposed at a center portion in the first direction DR1 may be defined as first center pads, and the first center pads may be disposed on a reference line VL. The reference line VL may be a virtual line disposed at the center portion of the display panel DP and parallel to the second direction DR2.

The first signal pads PD1 disposed on left and right sides of the reference line VL may be disposed to have a predetermined inclination with respect to the reference line VL. A portion of the first signal pads PD1 disposed on the left side of the reference line VL may be disposed to have an inclination in a first diagonal direction CDR1. The first signal pads PD1 disposed on the left side of the first center pads may be disposed to form an acute angle in a clockwise direction with respect to the reference line VL. A portion of the first signal pads PD1 disposed on the right side with respect to the reference line VL may be disposed to have an inclination in a second diagonal direction CDR2. The first signal pads PD1 disposed to the right side of the first center pads may be disposed to form an acute angle in a counterclockwise direction with respect to the reference line VL.

In the second signal pads PD2, the second signal pads PD2 disposed at the center portion in the first direction DR1 may be defined as the second center pad, and the second center pad may be disposed on the reference line VL. In the second signal pads PD2, the second signal pads PD2 disposed at the left and right sides of the reference line VL may be disposed to have a predetermined inclination with respect to the reference line VL. A portion of the second signal pads PD2 disposed at the left side with respect to the reference line VL may be disposed to form an acute angle in the clockwise direction with respect to the reference line VL. A portion of the second signal pads PD2 disposed at the right side with respect to the reference line VL may be disposed to form an acute angle in the counterclockwise direction with respect to the reference line VL.

The display panel DP (see FIG. 6) may further include a third pad PD3. The third pad PD3 may be disposed in the first pad area PA1. The third pad PD3 may be disposed between the first signal pad PD1 and the second signal pad PD2 and may not overlap the auxiliary circuit part TLP. The first organic film OM1 and the second organic film OM2 may be spaced apart from each other with the third pad PD3 therebetween.

The third pad PD3 may be provided in plurality, and the third pads PD3 may be disposed adjacent to the left and right edge portions of the first pad area PA1, respectively. The third pad PD3 may include a first sub-pad and a second sub-pad, which may be spaced apart from each other with the auxiliary circuit part TLP therebetween. The first sub-pad may be disposed at the left side with respect to the reference line VL, and the second sub-pad may be disposed at the right side with respect to the reference line VL. The first insulating opening OH1 and the second insulating opening OH2 may be spaced apart from each other with the third pad PD3 therebetween.

At least a portion of the third pad PD3 may be made of the same material as the first signal pad PD1 or the second signal pad PD2. Another portion of the third pad PD3 may function as an alignment pad. A portion of the third pads PD3 may be an identification mark or an alignment mark for checking alignment. For example, the third pads PD3 may be used as an identification mark or an alignment mark for checking alignment when bonding the driving chip DDV (see FIG. 6).

The display panel DP may further include an alignment pad ALP. The alignment pad ALP may be disposed in the first pad area PA1. The alignment pad ALP may be provided in plurality, and the alignment pads ALP may be disposed adjacent to the left and right edge portions of the first pad area PA1, respectively.

The alignment pad ALP may be an identification mark or an alignment mark. The alignment pad ALP may be used to check alignment when bonding the driving chip DDV (see FIG. 6). FIG. 8 illustrates an example of a cross-shaped alignment pad ALP, but the shape of the alignment pad ALP is not particularly limited. The shape of the alignment pad ALP may be any shape that may be used to align the driving chip DDV (see FIG. 6) and the display panel DP. For example, the alignment pad ALP may have a circular or polygonal shape.

The alignment pad ALP may include the same material as a portion of the third pads PD3. The alignment pad ALP may be formed through the same process as a portion of the third pads PD3. However, this is merely an example, and the alignment pad ALP may be made of a material different from that of the third pad PD3. The alignment pad ALP may be formed through a process different from that of the third pad PD3.

The first insulating opening OH1 may have a rectangular shape on the plane. FIG. 8 illustrates an example in which the first insulating opening OH1 has a rectangular shape with long sides in the first direction DR1 and short sides in the second direction DR2.

The first organic film OM1 may be disposed to fill at least a portion of the first insulating opening OH1. The first organic film OM1 may be disposed to fill the entire first insulating opening OH1. The first organic film OM1 may include a first portion M1-P1 and a third portion M1-P3 extending from the first portion M1-P1. In the first organic film OM1, the first portion M1-P1 may extend in the first direction DR1 to fill the first insulating opening OH1. In the first organic film OM1, the third portion M1-P3 may be a portion extending in a direction different from the first direction DR1. In the first organic film OM1, the third portion M1-P3 may be a portion extending in a direction away from the second signal pad PD2. In the first organic film OM1, the third portion M1-P3 may be a portion extending in a first diagonal direction CDR1 inclined with respect to the first direction DR1 and/or a second direction DR2 intersecting the first direction DR1. The first diagonal direction CDR1 and/or the second direction DR2 may be a direction away from the second signal pad PD2. Thus, in the first organic film OM1, the third portion M1-P3 may surround at least a portion of the first signal pads PD1 disposed adjacent to an edge area of the first pad area PA1 in the first signal pads PD1 and may be disposed to be spaced apart from the first signal pads PD1 at a predetermined distance.

The second organic film OM2 may be disposed to fill at least a portion of the second insulating opening OH2. The second organic film OM2 may be disposed to fill the entire second insulating opening OH2. The second organic film OM2 may include a second portion M2-P2 and a fourth portion M2-P4 extending from the second portion M2-P2. In the second organic film OM2, the second portion M2-P2 may extend in the first direction DR1 and fill the second insulating opening OH2. In the second organic film OM2, the fourth portion M2-P4 may be a portion extending in a direction different from the first direction DR1. In the second organic film OM2, the fourth portion M2-P4 may be a portion extending in a direction away from the first signal pad PD1. In the second organic film OM2, the fourth portion M2-P4 may be a portion extending in a direction opposite to the first diagonal direction CDR1 inclined with respect to the first direction DRI and/or a direction opposite to the second direction DR2 intersecting the first direction DR1. The direction opposite to the first diagonal direction CDR1 may mean a direction opposite (away from) the first diagonal direction CDR1 on a straight line. The direction opposite to the second direction DR2 may mean a direction opposite (away from) the second direction DR2 on the straight line. The direction opposite to the first diagonal direction CDR1 and/or the direction opposite to the second direction DR2 may be a direction away from the first signal pad PD1. Thus, in the second organic film OM2, the fourth portion M2-P4 may surround at least a portion of the second signal pads PD2 disposed adjacent to an edge area of the first pad area PA1 in the second signal pads PD2 and be disposed to be spaced apart from the second signal pads PD2 at a predetermined distance.

The first organic film OM1 may be spaced apart from the second signal pad PD2 with the second organic film OM2 therebetween. The second organic film OM2 may be spaced apart from the first signal pad PD1 with the first organic film OM1 therebetween.

Each of the first and second organic films OM1 and OM2 may function as a dam. As described herein, each of the first conductive adhesive layer AF1 (see FIG. 6) and the second conductive adhesive layer AF2 (see FIG. 6) may include an adhesive resin and conductive particles dispersed in the adhesive resin. When bonding the driving chip DDV (see FIG. 6) and/or the flexible circuit board FCB (see FIG. 6), the conductive particles may move in a direction toward the first or second signal pads PD1 and PD2 according to a flow of adhesive resin due to the bonding. These conductive particles may be agglomerated at the first or second signal pads PD1 and PD2, and may cause a short circuit. In the display device EA (see FIG. 2) according to an embodiment, each of the first and second organic films OM1 and OM2 may serve as the dam to inhibit or prevent the agglomeration of the conductive particles. Thus, the display device EA (see FIG. 2) may inhibit or prevent a short circuit, and may have improved reliability.

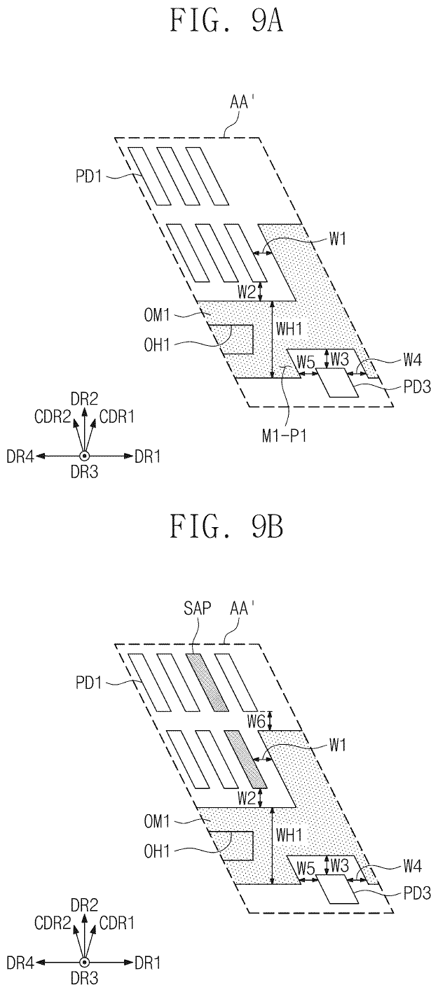

FIG. 9A is an enlarged cross-sectional view of an area AA′ of FIG. 8. Referring to FIG. 9A, in the first signal pads PD1, the first signal pad PD1 disposed closest to the first organic film OM1 in the first direction DR1 may be spaced a first interval W1 from the first organic film OM1 in the first direction DR1. In the first signal pads PD1, the first signal pad PD1 disposed closest to the first organic film OM1 in the second direction DR2 may be spaced a second interval W2 from the first organic film OM1 in the second direction DR2.

Each of the first and second intervals W1 and W2 may be greater than about 0 um. For example, each of the first and second intervals W1 and W2 may be about 30 um. As the first organic film OM1 may be disposed to be spaced apart from the first signal pad PD1 by the first and second intervals W1 and W2, improved processability may be achieved.

The first organic film OM1 may surround at least a portion of the third pad PD3 and may be disposed to be spaced a predetermined interval from the third pad PD3. In the third pads PD3, the third pad PD3 disposed closest to the first organic film OM1 in the second direction DR2 may be spaced a third interval W3 from the first organic film OM1 in the second direction DR2. In the third pads PD3, the third pad PD3 disposed closest to the first organic film OM1 in the first direction DR1 may be spaced a fourth interval W4 from the first organic film OM1 in the first direction DR1. In the third pads PD3, the third pad PD3 disposed closest to the first organic film OM1 in the fourth direction DR4 may be spaced a fifth interval W5 from the first organic film OM1 in the fourth direction DR4. The fourth direction DR4 may be a direction opposite to the first direction DR1 on the straight line.

Each of the third to fifth intervals W3, W4, and W5 may be greater than about 0 um. For example, each of the third to fifth intervals W3, W4, and W5 may be about 30 um. As the first organic film OM1 may be disposed to be spaced apart from the third pad PD3 by the third to fifth intervals W3, W4, and W5, improved processability may be achieved.

A width WH1 of the first portion M1-P1 in the first organic film OM1 may be about 100 micrometers (μm). The width WH1 of the first portion M1-P1 may be a width of the first portion M1-P1 in the second direction DR2 in a center portion of the first pad area PA1 and between the first signal pads PD1 and the auxiliary circuit part TLP. However, this is merely an example, and the width WH1 of the first portion M1-P1 is not limited thereto.

FIG. 9B is a plan view of an area AA′ according to another embodiment of the inventive concept. In the description of FIG. 9B, repeated descriptions content that overlap those described with reference to FIGS. 1 to 9A may be omitted or simplified.

Referring to FIG. 9B, a sub-align pad SAP may be disposed. Specifically, FIG. 9B illustrates an example in which the sub-align pad SAP may be disposed at a portion of the position at which the first signal pad PD1 is disposed in FIG. 9A. The sub-align pad SAP may be disposed adjacent to an edge area of the first pad area PA1. In the first direction DR1, the first signal pad PD1 and the first organic film OM1 may be spaced apart from each other with the sub-align pad SAP therebetween. The sub-align pad SAP may be provided in plurality, and the sub-align pads SAP may be arranged in different rows from the rows in which the first signal pads PD1 are arranged. The sub-align pad SAP may be an identification mark or an align mark to check alignment when bonding the driving chip DDV (see FIG. 6). The arrangement of the sub-align pad SAP in FIG. 9B is merely an example and is not limiting to any embodiment.

In the first signal pads PD1, the first signal pad PD1 disposed closest to the first organic film OM1 in the second direction DR2 may be spaced a sixth interval W6 from the first organic film OM1 in the second direction DR2. The sixth interval W6 may be greater than about 0 um. For example, the sixth interval W6 may be about 30 um. The sixth interval W6 may be substantially equal to the second interval W2. As the first organic film OM1 may be disposed to be spaced apart from the first signal pad PD1 by the sixth interval W6, improved processability may be achieved.

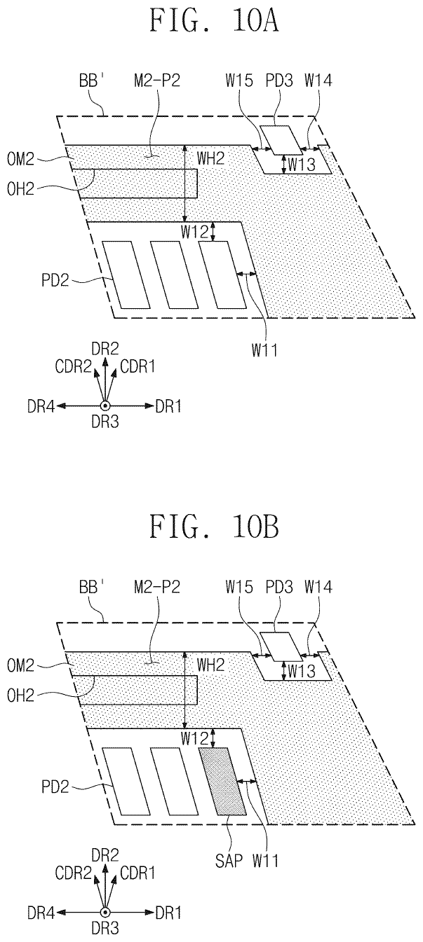

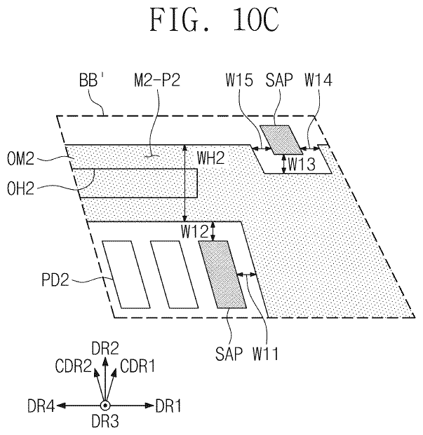

FIG. 10A shows an enlarged plan view of an area BB′ of FIG. 8. Referring to FIG. 10A, in the second signal pads PD2, the second signal pad PD2 disposed closest to the second organic film OM2 in the first direction DR1 may be spaced a seventh interval W11 from the second organic film OM2 in the first direction DR1. In the second signal pads PD2, the second signal pad PD2 disposed closest to the second organic film OM2 in the second direction DR2 may be spaced an eighth interval W12 from the second organic film OM2 in the second direction DR2.

Each of the seventh and eighth intervals W11 and W12 may be greater than about 0 um. For example, each of the seventh and eighth intervals W11 and W12 may be about 30 um. As the second organic film OM2 is disposed to be spaced apart from the second signal pad PD2 by the seventh and eighth intervals W11 and W12, improved processability may be achieved.

The second organic film OM2 may surround at least a portion of the third pad PD3 and may be disposed to be spaced from the third pad PD3 by a predetermined interval. In the third pads PD3, the third pad PD3 disposed closest to the second organic film OM2 in the second direction DR2 may be spaced a ninth interval W13 from the second organic film OM2 in the second direction DR2. In the third pads PD3, the third pad PD3 disposed closest to the second organic film OM2 in the first direction DR1 may be spaced a tenth interval W14 from the second organic film OM2 in the first direction DR1. In the third pads PD3, the third pad PD3 disposed closest to the second organic film OM2 in the fourth direction DR4 may be spaced an eleventh interval W15 from the second organic film OM2 in the fourth direction DR4.

Each of the ninth to eleventh intervals W13, W14, and W15 may be greater than about 0 um. For example, each of the ninth to eleventh intervals W13, W14, and W15 may be about 30 um. In a case that the second organic film OM2 is disposed to be spaced apart from the third pad PD3 by the ninth to eleventh intervals W13, W14, and W15, improved processability may be achieved.

A width WH2 of the second portion M2-P2 in the second organic film OM2 may be about 100 um. The width WH2 of the second portion M2-P2 may be a width of the second portion M2-P2 in the second direction DR2 in a center portion of the first pad area PA1 and between the second signal pads PD2 and the auxiliary circuit part TLP. However, this is merely an example, and the width WH2 of the second portion M2-P2 is not limited thereto.

FIGS. 10B and 10C are plan views of an area BB' according to another embodiment of the inventive concept. In the description of FIGS. 10B and 10C, repeated descriptions of contents that overlap those described with reference to FIGS. 1 to 10A may be omitted or simplified.

Referring to FIG. 10B, a sub-align pads SAP may be further disposed. Specifically, FIG. 10B illustrates an example in which the sub-align pad SAP may be disposed at a portion of the positions at which the second signal pad PD2 is disposed in FIG. 10A. In the first direction DR1, the second signal pad PD2 and the second organic film OM2 may be spaced apart from each other with the sub-align pad SAP therebetween. The arrangement of the sub-align pad SAP in FIG. 10B is merely an example and is not limited to any embodiment.

Referring to FIG. 10C, a sub-align pads SAP may be further disposed. Specifically, FIG. 10C illustrates an example in which the sub-align pad SAP may be disposed at a portion of the positions at which the second signal pad PD2 is disposed in FIG. 10A. In addition, FIG. 10C illustrates an example in which the sub-align pad SAP may be disposed at a position at which the third pad PD3 is disposed in FIG. 10A. In the first direction DR1, the second signal pad PD2 and the second organic film OM2 may be spaced apart from each other with the sub-align pad SAP therebetween. The arrangement of the sub-align pad SAP in FIG. 10C is merely an example and is not limited to any embodiment.

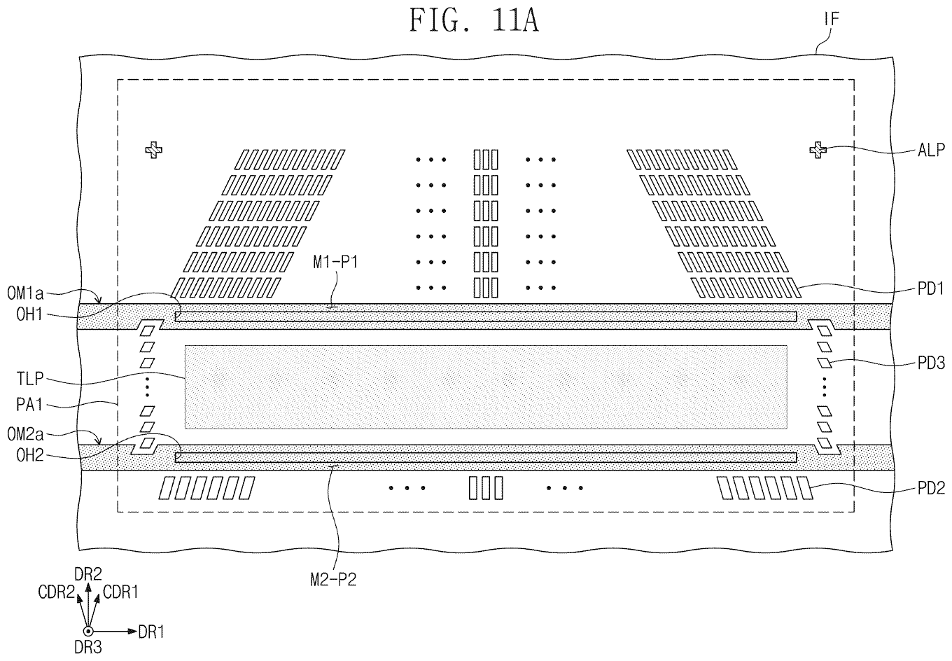

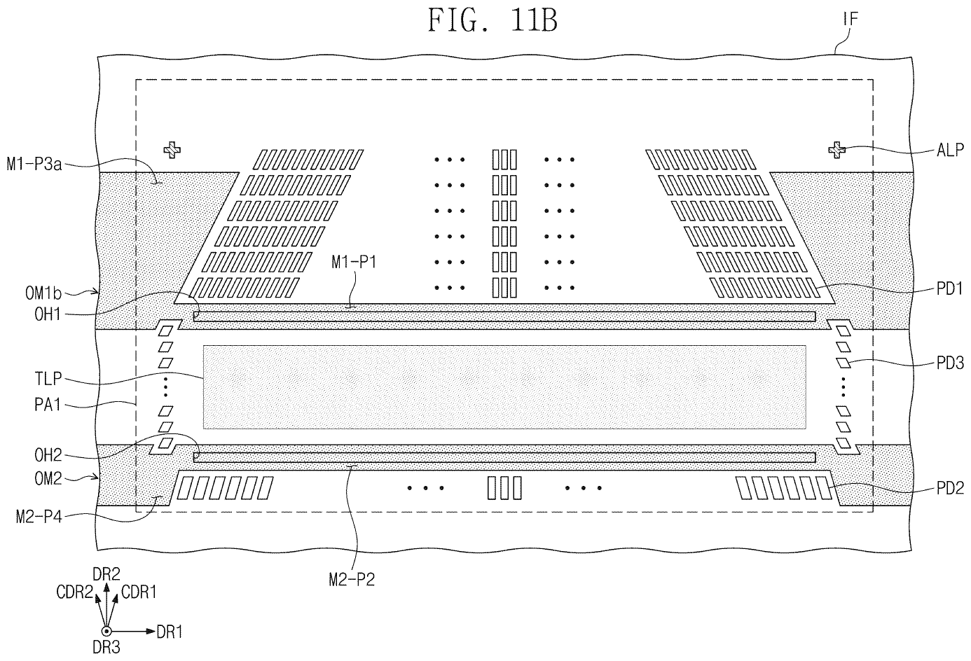

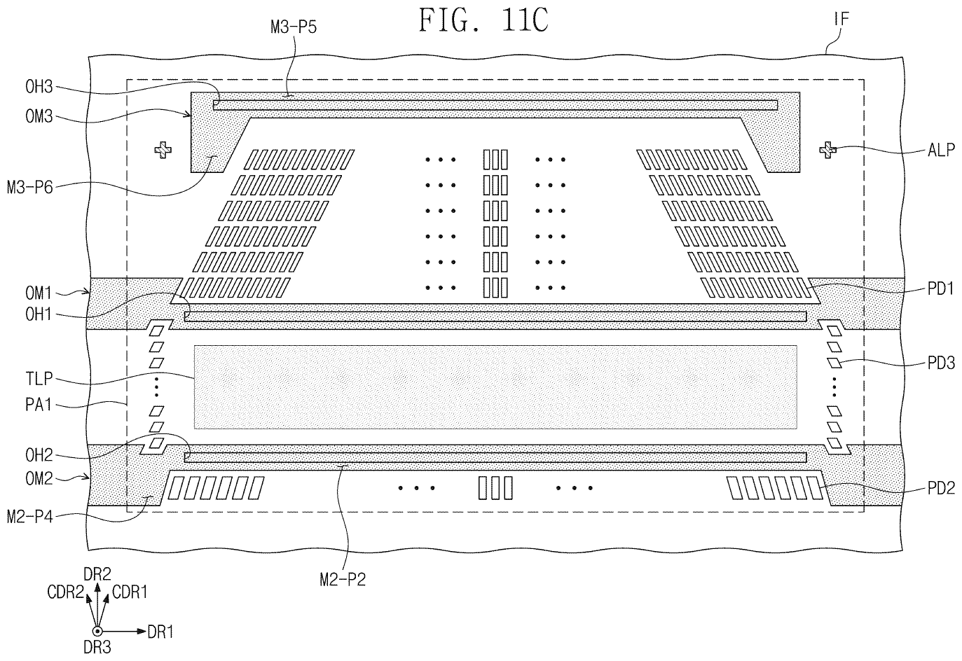

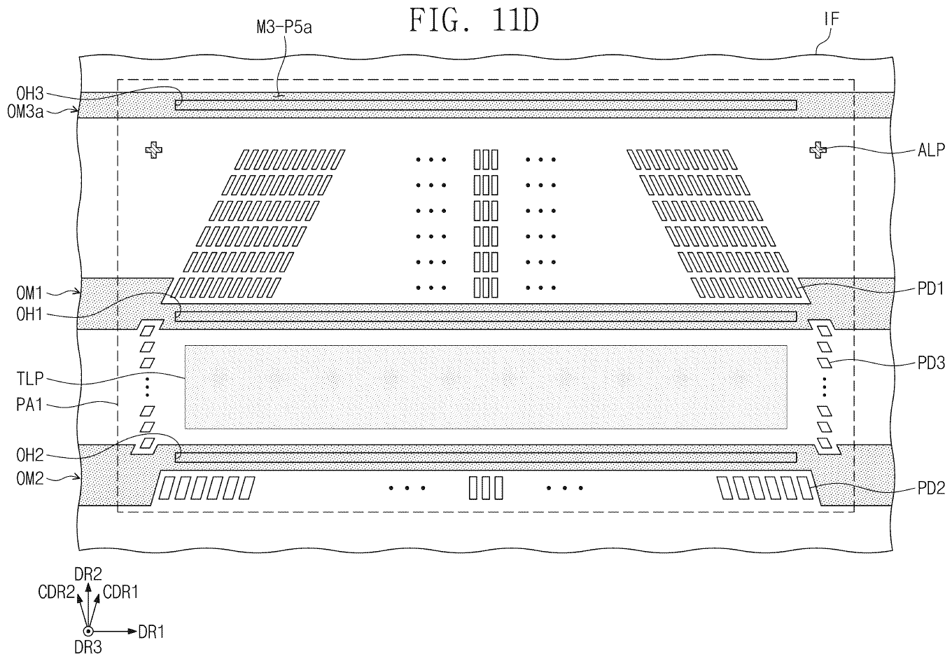

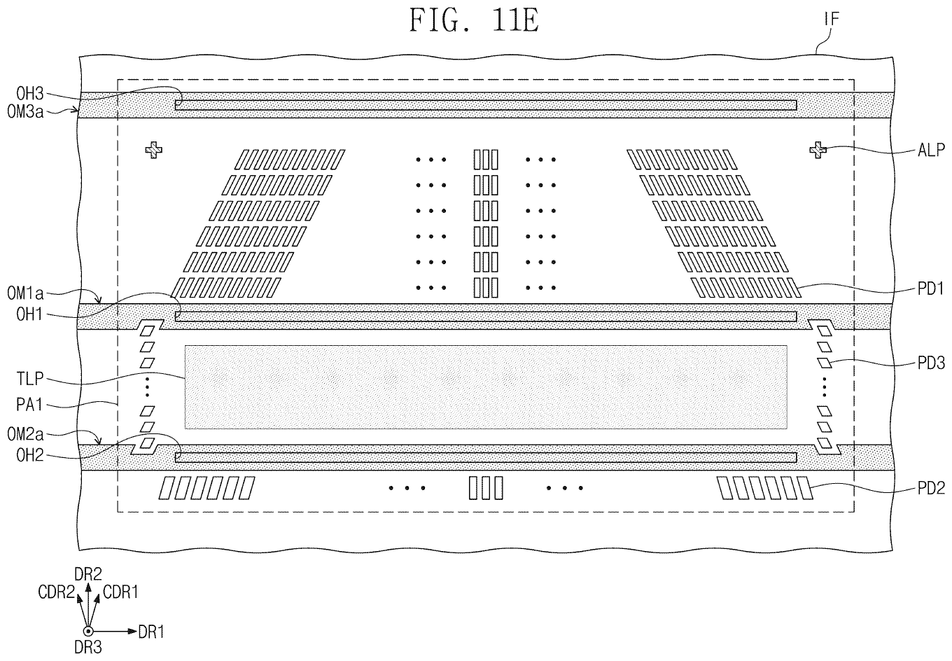

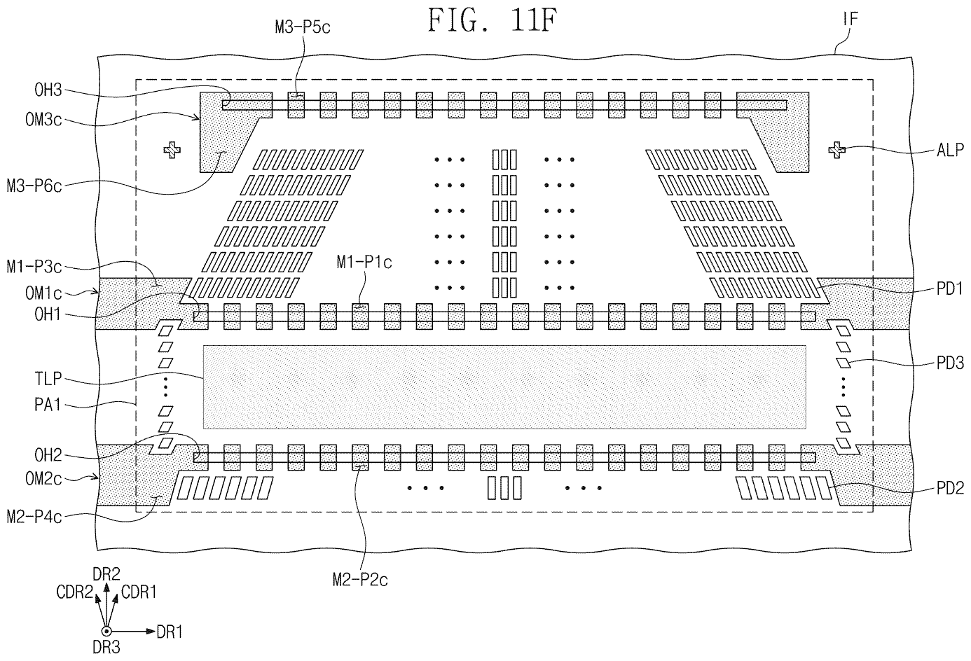

FIGS. 11A, 11B, 11C, 11D, 11E, and 11F are plan views illustrating some of configurations of the display panel DP (see FIG. 6) according to another embodiment of the inventive concept. In the description of FIGS. 11A to 11F, repeated descriptions of contents that overlap those described with reference to FIGS. 1 to 10B may be omitted or simplified.

Referring to FIG. 11A, first and second organic films OM1a and OM2a may be provided. When the first organic film OM1 of FIG. 8 includes the first portion M1-P1 and does not include the third portion M1-P3, the first organic film OM1 of FIG. 8 may correspond to a first organic film OM1a of FIG. 11A. When the second organic film OM2 of FIG. 8 includes the second portion M2-P2 and does not include the fourth portion M2-P4, the second organic film OM2 of FIG. 8 may correspond to a second organic film OM2a of FIG. 11A.

Referring to FIG. 11B, a first organic film OM1b may be provided. For example, a third portion M1-P3a of the first organic film OM1b of FIG. 11B may extend in the second direction DR2 and/or the first diagonal direction CDR1. The third portion M1-P3a may further extend in a direction away from the second signal pad PD2. In the first organic film OM1 of FIG. 8, the third portion M1-P3 may surround a portion of a row closest to the first insulating opening OH1 in six rows in which the first signal pads PD1 are arranged and be disposed to be spaced apart. Alternatively, in the first organic film OM1b of FIG. 11B, a third portion M1-P3a may surround a portion of five rows adjacent to the first insulating opening OH1 in six rows in which the first signal pads PD1 are arranged and be disposed to be spaced apart.

Referring to FIG. 11C, a third insulating opening OH3 may be spaced apart from the first insulating opening OH1 is defined with the first signal pad PD1 therebetween. Additionally, a third organic film OM3 may be disposed to fill at least a portion of the third insulating opening OH3.

The third insulating opening OH3 may be defined adjacent to the first signal pad PD1. The third insulating opening OH3 and the third organic film OM3 may inhibit or prevent a gap from forming at a position adjacent to the first signal pad PD1. Thus, corrosion of the first signal pad PD1 may be inhibited or prevented, and the display device EA (see FIG. 2) according to an embodiment may exhibit improved reliability.

The third organic film OM3 may fill the third insulating opening OH3. The third organic film OM3 may include a fifth portion M3-P5 and a sixth portion M3-P6 extending from the fifth portion M3-P5. In the third organic film OM3, the fifth portion M3-P5 may extend in the first direction DR1. In the third organic film OM3, the sixth portion M3-P6 may be a portion extending in a direction approaching the first and second signal pads PD1 and PD2. In the third organic film OM3, the sixth portion M3-P6 may be a portion extending in a direction different from the first direction DR1. In the third organic film OM3, the sixth portion M3-P6 may be a portion extending in a direction opposite to the second direction DR2 and/or in a direction opposite to the first diagonal direction CDR1. The direction opposite to the second direction DR2 and the direction opposite to the first diagonal direction CDR1 may be a direction inclined with respect to the first direction DR1. Thus, in the third organic film OM3, the sixth portion M3-P6 may surround at least a portion of the first signal pads PD1 disposed adjacent to an edge area of the first pad area PA1 in the first signal pads PD1 and be disposed to be spaced apart from the first signal pads PD1 at a predetermined distance.

The third organic film OM3 may include the same organic material as the first and second organic films OM1 and OM2. The third organic film OM3 may be disposed on the light emitting element OL and may include the same organic material as the member made of the organic material. The third organic film OM3 may include the same organic material as the organic material forming the input sensing layer ISP, the encapsulation layer ECL, or the optical layer RCL. The third organic film OM3 may include the same organic material as the sub-insulating layers IL2 and IL3 of the input sensing layer ISP, the organic encapsulation layer EN2 of the encapsulation layer ECL, and the over-layer OC of the optical layer RCL.

Referring to FIG. 11D, a third organic film OM3a may include a fifth portion M3-P5a and may not include a sixth portion M3-P6. In addition, the fifth portion M3-P5a of FIG. 11D may extend in the first direction DR1.

The first organic film OM1a and the second organic film OM2a in FIG. 11E are the same as the first organic film OM1a and the second organic film OM2a in FIG. 11A. The third organic film OM3a in FIG. 11E may be the same as the third organic film OM3a in FIG. 11D.

Referring to FIG. 11F, a plurality of sub-organic films M1-P1c, M1-P3c, M2-P2c, M2-P4c, M3-P5c, and M3-P6c may be arranged. The sub-organic films M1-P1c, M1-P3c, M2-P2c, M2-P4c, M3-P5c, and M3-P6c may be disposed to fill at least a portion of the first to third insulating openings OH1, OH2, and OH3.

Referring to FIG. 11F, the sub-organic films M1-P1c, M1-P3c, M2-P2c, M2-P4c, M3-P5c, and M3-P6c may not be disposed in some of the first to third insulating openings OH1, OH2, and OH3. Thus, a surface of the fourth insulating layer 40 (see FIGS. 7A and 7B) disposed under the insulating film IF may be exposed through a portion of the first to third insulating openings OH1, OH2, and OH3.

The first organic film OM1c may include a first sub-organic film M1-P1c and a second sub-organic film M1-P3c. The first sub-organic film M1-P1c may be provided in plurality, and the first sub-organic films M1-P1c may be spaced apart from each other in the first direction DR1. The second sub-organic film M1-P3c may be provided in plurality, and the second sub-organic films M1-P3c may be spaced apart from each other in the first direction DR1. In FIG. 11F, the second sub-organic films M1-P3c may be spaced apart from each other with the first sub-organic films M1-P1c therebetween.

The second organic film OM2c may include a third sub-organic film M2-P2c and a fourth sub-organic film M2-P4c. The third sub-organic film M2-P2c may be provided in plurality, and the third sub-organic films M2-P2c may be spaced apart from each other in the first direction DR1. The fourth sub-organic film M2-P4c may be provided in plurality, and the fourth sub-organic films M2-P4c may be spaced apart from each other in the first direction DR1. In FIG. 11F, the fourth sub-organic films M2-P4c may be spaced apart from each other with third sub-organic films M2-P2c therebetween.

The third organic film OM3c may include a fifth sub-organic film M3-P5c and a sixth sub-organic film M3-P6c. The fifth sub-organic film M3-P5c may be provided in plurality, and the fifth sub-organic films M3-P5c may be spaced apart in the first direction DR1. The sixth sub-organic film M3-P6c may be provided in plurality, and the sixth sub-organic films M3-P6c may be spaced apart from each other in the first direction DR1. In FIG. 11F, the sixth sub-organic films M3-P6c may be spaced apart from each other with fifth sub-organic films M3-P5c therebetween. In an embodiment, the organic films OM1c, OM2c, and OM3c filling at least a portion of the insulating openings OH1, OH2, and OH3 may include the plurality of sub-organic films M1-P1c, M1-P3c, M2-P2c, M2-P4c, M3-P5c, and M3-P6c, a flow of the adhesive resin may be easy. As described herein, each of the first conductive adhesive layer AF1 (see FIG. 6) and the second conductive adhesive layer AF2 (see FIG. 6) may include an adhesive resin and conductive particles dispersed in the adhesive resin. During the bonding process, the adhesive resin may flow vertically and horizontally on the plane, and the organic films OM1c, OM2c, and OM3c may include the sub-organic films M1-P1c, M1-P3c, M2-P2c, M2-P4c, M3-P5c, and M3-P6c, but may not have the single shape, and thus, the flow of the adhesive resin may be easy.

The display device according to an embodiment may include the insulating film, in which the insulating opening is defined, and the organic film disposed to fill at least a portion of the insulating opening. The organic film may be disposed on the light emitting element and may include the same organic material as the member made of the organic material. As the organic film is disposed, the cracks in the display panel may be inhibited or prevented when bending and/or bonding the display panel. Thus, the display device according to an embodiment may exhibit the improved rigidity and reliability.

The display device according to embodiments may include the organic film that fills the opening defined in the insulating film to improve rigidity and reliability.

It will be apparent to those skilled in the art that various modifications and variations can be made in the inventive concept. Thus, it is intended that the present disclosure covers the modifications and variations of this invention provided they come within the scope of the appended claims and their equivalents.

What is claimed is:

1. A display device comprising:
a display area;
a bending area extending from the display area;
a non-display area extending from the display area with the bending area disposed therebetween, the non-display area including;
a first signal pad;
a second signal pad spaced apart from the display area with the first signal pad disposed therebetween;
an auxiliary circuit part disposed between the first signal pad and the second signal pad;
an organic protective layer overlapping the auxiliary circuit part;
an insulating film having a first insulating opening defined between the first signal pad and the auxiliary circuit part and a second insulating opening defined between the second signal pad and the auxiliary circuit part, the insulating film being disposed on the organic protective layer;
a first organic film disposed to fill at least a portion of the first insulating opening; and
a second organic film disposed to fill at least a portion of the second insulating opening.

2. The display device of claim 1, wherein the first organic film and the second organic film cover respective edge portions of the insulating film defining the first insulating opening and the second insulating opening, and
wherein the first organic film and the second organic film are disposed apart from the first signal pad and the second signal pad.

3. An electronic device comprising:
a light emitting element disposed in a first base area;
a first signal pad electrically connected to the light emitting element and disposed in a second base area adjacent to the first base area;
a second signal pad spaced apart from the first base area with the first signal pad disposed therebetween and disposed in the second base area;
an auxiliary circuit part disposed between the first signal pad and the second signal pad in the second base area;
an organic protective layer overlapping the auxiliary circuit part and disposed in the second base area;
an insulating film having a first insulating opening defined between the first signal pad and the auxiliary circuit part and a second insulating opening defined between the second signal pad and the auxiliary circuit part, the insulating film being disposed on the organic protective layer in the second base area;
a first organic film disposed to fill at least a portion of the first insulating opening in the second base area; and
a second organic film disposed to fill at least a portion of the second insulating opening in the second base area.

4. The electronic device of claim 3, wherein the first base area includes a display area and the second base area includes a non-display area, and
the first organic film and the second organic film are spaced apart from each other with the organic protective layer therebetween in a direction perpendicular to a thickness direction.

5. The electronic device of claim 3, wherein each of the first organic film and the second organic film does not overlap the first signal pad and the second signal pad.

6. The electronic device of claim 3, further comprising an input sensing layer comprising a sensing conductive layer and a sub-insulating layer disposed on the sensing conductive layer, the input sensing layer being disposed on the light emitting element,
wherein each of the first organic film and the second organic film comprises the same organic material as the sub-insulating layer.

7. The electronic device of claim 3, further comprising an organic encapsulation layer disposed on the light emitting element,
wherein each of the first organic film and the second organic film comprises the same organic material as the organic encapsulation layer.

8. The electronic device of claim 3, further comprising an optical layer comprising at least one of a pigment or a dye and disposed on the light emitting element,
wherein each of the first organic film and the second organic film comprises the same organic material as the optical layer.

9. The electronic device of claim 8, wherein the optical layer comprises:
an optical pattern part in which a pattern opening is defined; and
a sub-optical layer comprising at least one of the pigment or the dye and configured to serve as a planarization layer disposed to fill the pattern opening,
wherein each of the first organic film and the second organic film comprises the same organic material as the sub-optical layer.

10. The electronic device of claim 8, wherein the optical layer comprises:
an optical pattern part in which a pattern opening is defined;
a filter part comprising at least one of the pigment or the dye and disposed to fill the pattern opening; and
an over-layer disposed on the optical pattern part and the filter part,
wherein each of the first organic film and the second organic film comprises the same organic material as the over-layer.

11. The electronic device of claim 10, wherein the light emitting element comprises a first electrode, a second electrode disposed on the first electrode, and an emission layer disposed between the first electrode and the second electrode, and
the filter part overlaps the emission layer.

12. The electronic device of claim 3, wherein, on a plane, the first organic film comprises a first portion extending in a first direction perpendicular to a thickness direction, and the second organic film comprises a second portion extending in the first direction,
wherein the first organic film further comprises a third portion extending from the first portion in a second direction different from the first direction, and
wherein the second direction is a direction away from the second signal pad.

13. The electronic device of claim 3, wherein, on a plane, the first organic film comprises a first portion extending in a first direction perpendicular to a thickness direction, and the second organic film comprises a second portion extending in the first direction,
wherein, on the plane, the second organic film further comprises a fourth portion extending from the second portion in a third direction different from the first direction, and
wherein the third direction is a direction away from the first signal pad.

14. The electronic device of claim 3, wherein each of the first organic film and the second organic film comprises a plurality of sub-organic films spaced apart from each other in a direction perpendicular to a thickness direction.

15. The electronic device of claim 3, wherein the insulating film overlaps an edge portion of the first signal pad and an edge portion of the second signal pad, and
wherein the insulating film has a first pad opening exposing the first signal pad and a second pad opening exposing the second signal pad.

16. The electronic device of claim 3, wherein the auxiliary circuit part comprises an auxiliary line disposed on the same layer as at least one of the first signal pad or the second signal pad.

17. A display device comprising:
a light emitting element disposed in a first base area;
a first signal pad electrically connected to the light emitting element and disposed in a second base area adjacent to the first base area;
a second signal pad spaced apart from the first base area with the first signal pad disposed therebetween and disposed in the second base area;
an insulating film having a first insulating opening defined between the first signal pad and the second signal pad, and a second insulating opening spaced apart from the first insulating opening with the first signal pad therebetween, the insulating film being disposed in the second base area;
a first organic film disposed to fill at least a portion of the first insulating opening in the second base area; and
a second organic film disposed to fill at least a portion of the second insulating opening in the second base area.

18. The display device of claim 17, further comprising:
an auxiliary circuit part disposed between the first signal pad and the second signal pad in the second base area;
an organic protective layer overlapping the auxiliary circuit part and disposed in the second base area,
wherein the insulating film is disposed on the organic protective layer in the second base area,
wherein the first insulating opening is defined between the first signal pad and the auxiliary circuit part, and
wherein the insulating film further comprises a third insulating opening defined between the second signal pad and the auxiliary circuit part; and
a third organic film disposed to fill at least a portion of the third insulating opening in the second base area.

19. The display device of claim 18, wherein, on a plane, the third organic film comprises a fifth portion extending in a first direction perpendicular to a thickness direction.

20. The display device of claim 19, wherein, on the plane, the third organic film further comprises a sixth portion extending from the fifth portion in a fourth direction different from the first direction,
wherein the fourth direction is a direction approaching the second signal pad.
